(19) United States
(12) Patent Application Publication
(10) Pub. No.: US 2015/0137388 A1
(43) Pub. Date: May 21, 2015

(54) SEMICONDUCTOR DEVICES

(71) Applicants: Eun-Ji KIM, Seoul (KR); Sung-Dong CHO, Hwaseong-si (KR); Sin-Woo KANG, Suwon-si (KR); Myung-Soo JANG, Seoul (KR); Yeong-Lyeol PARK, Yongin-si (KR); Seung-Teak LEE, Bucheon-si (KR)

(72) Inventors: Eun-Ji KIM, Seoul (KR); Sung-Dong CHO, Hwaseong-si (KR); Sin-Woo KANG, Suwon-si (KR); Myung-Soo JANG, Seoul (KR); Yeong-Lyeol PARK, Yongin-si (KR); Seung-Teak LEE, Bucheon-si (KR)

(21) Appl. No.: 14/549,518

(22) Filed: Nov. 20, 2014

(30) Foreign Application Priority Data
Nov. 21, 2013 (KR) 10-2013-0141956

(51) Int. Cl. H01L 23/522; H01L 23/528

(52) U.S. Cl. CPC H01L 23/5226; H01L 23/528
USPC 257/774

(57) ABSTRACT

A semiconductor device includes a first low-k dielectric layer structure including at least one first low-k dielectric layer sequentially stacked on a substrate, a via structure extending through at least a portion of the substrate and the first low-k dielectric layer structure, and a first blocking layer pattern structure spaced apart from the via structure in the first low-k dielectric layer structure. The first blocking layer pattern structure surrounds a sidewall of the first blocking layer structure.

### CROSS-REFERENCE TO RELATED APPLICATION

This application claims priority under 35 USC §119 to Korean Patent Application No. 10-2013-0141956, filed on Nov. 21, 2013 in the Korean Intellectual Property Office (KIPO), the contents of which are herein incorporated by reference in their entirety.

### BACKGROUND

1. Field

Embodiments relate to a semiconductor device and a method of manufacturing the same, a semiconductor package including the semiconductor device and a method of manufacturing the same. More particularly, embodiments relate to a semiconductor device having a via structure and a method of manufacturing the same, a semiconductor package including the semiconductor device and a method of manufacturing the same.

2. Description of the Related Art

As semiconductor devices have been highly integrated, a three-dimensional packaging technology in which multiple chips may be stacked on each other has been developed. A through silicon via (TSV) technology is a packaging technology in which a via hole may be formed through a silicon substrate and a via electrode may be formed in the via hole.

However, an insulation layer in which wirings may be formed may be damaged due to chemicals for forming the via hole, and the insulation layer may be stressed due to the difference of thermal expansion coefficients between the insulation layer and a metal used for forming the via electrode, so that the reliability of a semiconductor device including the via electrode may be lowered.

### SUMMARY

An embodiment includes a semiconductor device including a first low-k dielectric layer structure including at least one first low-k dielectric layer sequentially stacked on a substrate, a via structure extending through at least a portion of the substrate and the first low-k dielectric layer structure, and a first blocking layer pattern structure spaced apart from the via structure in the first low-k dielectric layer structure. The first blocking layer pattern structure surrounds a sidewall of the first blocking layer structure.

An embodiment includes a semiconductor device, comprising: an insulating interlayer on a substrate; a low-k dielectric layer structure including at least one low-k dielectric layer sequentially stacked on the insulating interlayer; a via structure through at least a portion of the substrate and the insulating interlayer; a contact structure on the via structure, the contact structure disposed in the low-k dielectric layer structure; and a blocking layer pattern structure spaced apart from the contact structure in the low-k dielectric layer structure, the blocking layer pattern structure surrounding a sidewall of the contact structure.

An embodiment includes a method, comprising: forming a first low-k dielectric layer structure on a substrate; forming a first blocking layer pattern structure in the first low-k dielectric layer structure; and forming a via structure through the first low-k dielectric layer structure and at least a portion of the substrate to be spaced apart from the first blocking layer pattern structure such that a portion of a sidewall of the via structure is surrounded by the first blocking layer pattern structure.

An embodiment includes a semiconductor package, comprising: a first semiconductor chip including: a first low-k dielectric layer structure including at least one first low-k dielectric layer sequentially stacked on a substrate; a via structure extending through the substrate and the first low-k dielectric layer structure; and a blocking layer pattern structure spaced apart from the via structure in the first low-k dielectric layer structure, the blocking layer pattern structure surrounding a sidewall of the via structure; and a second semiconductor chip electrically connected to the first semiconductor chip through the via structure.

An embodiment includes a semiconductor device, comprising: a circuit formed on a substrate a low-k dielectric layer formed on the substrate; wirings electrically connected to the circuit and formed in the low-k dielectric layer; a conductive structure including a via structure, the conductive structure extending through the low-k dielectric layer and at least part of the substrate; and a blocking layer pattern structure disposed in the low-k dielectric layer and surrounding a sidewall of the conductive structure.

### BRIEF DESCRIPTION OF THE DRAWINGS

Embodiments will be more clearly understood from the following detailed description taken in conjunction with the accompanying drawings.

FIG. 1 is a vertical cross-sectional view illustrating a semiconductor device in accordance with some embodiments, and FIGS. 2 to 4 are horizontal cross-sectional views illustrating examples of the semiconductor device;

FIGS. 5, 6, 8 and 9 to 18 are vertical cross-sectional views illustrating stages of a method of manufacturing a semiconductor device in accordance with some embodiments, and FIGS. 7 and 19 are plan views illustrating various stages of the method of manufacturing the semiconductor device;

FIG. 20 is a vertical cross-sectional view illustrating a semiconductor device in accordance with some embodiments, and FIG. 21 is a horizontal cross-sectional view illustrating the semiconductor device;

FIG. 22 is a vertical cross-sectional view illustrating a semiconductor device in accordance with some embodiments;

FIG. 23 is a cross-sectional view illustrating a stage of a method of manufacturing a semiconductor device in accordance with some embodiments;

FIG. 24 is a vertical cross-sectional view illustrating a semiconductor device in accordance with some embodiments;

FIG. 25 is a vertical cross-sectional view illustrating a semiconductor device in accordance with some embodiments;

FIG. 26 is a vertical cross-sectional view illustrating a semiconductor device in accordance with some embodiments;

FIGS. 27 and 28 are cross-sectional views illustrating stages of a method of manufacturing a semiconductor device in accordance with some embodiments;

FIG. 29 is a vertical cross-sectional view illustrating a semiconductor device in accordance with some embodiments;

FIG. 30 is a cross-sectional view illustrating a stage of a method of manufacturing a semiconductor device in accordance with some embodiments;

FIG. 31 is a vertical cross-sectional view illustrating a semiconductor package in accordance with some embodiments;

FIGS. 32 to 37 are cross-sectional views illustrating stages of a method of manufacturing a semiconductor package in accordance with some embodiments;

FIG. 38 is a vertical cross-sectional view illustrating a semiconductor device in accordance with some embodiments;

FIGS. 39 to 41 are cross-sectional views illustrating stages of a method of manufacturing a semiconductor package in accordance with some embodiments;

FIG. 42 is a vertical cross-sectional view illustrating a semiconductor package in accordance with some embodiments;

FIG. 43 is a vertical cross-sectional view illustrating a semiconductor device in accordance with some embodiments; and

FIG. 44 is a schematic view of an electronic system which may include a semiconductor package in accordance with some embodiments.

### DESCRIPTION OF EMBODIMENTS

Various embodiments will be described more fully hereinafter with reference to the accompanying drawings, in which exemplary embodiments are shown. Embodiments may, however, take many different forms and should not be construed as limited to the particular embodiments set forth herein. Rather, these embodiments are provided so that this description will be thorough and complete, and will fully convey the scope to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings herein.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Some embodiments are described herein with reference to cross-sectional illustrations that are schematic illustrations of idealized some embodiments (and intermediate structures). As such, variations from the shapes of the illustrations as a result, for example, of manufacturing techniques and/or tolerances, are to be expected. Thus, some embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

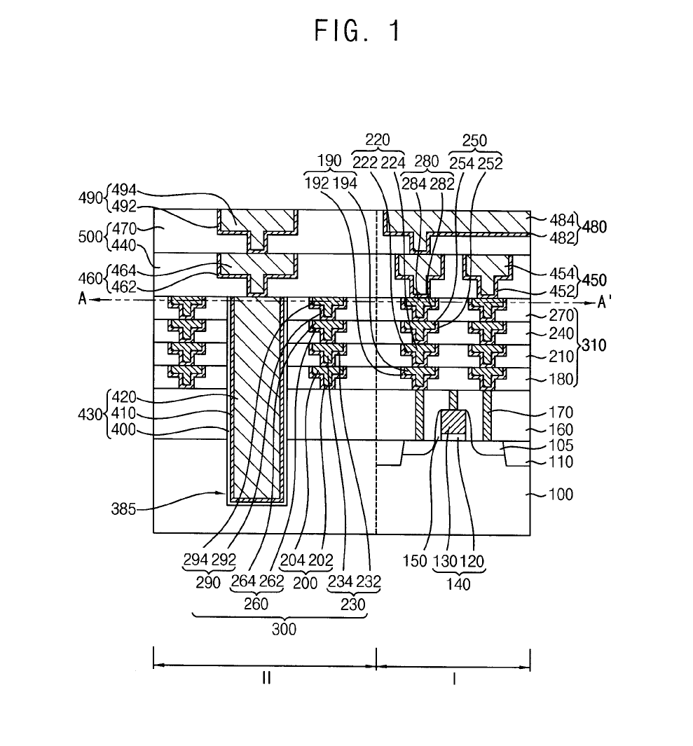

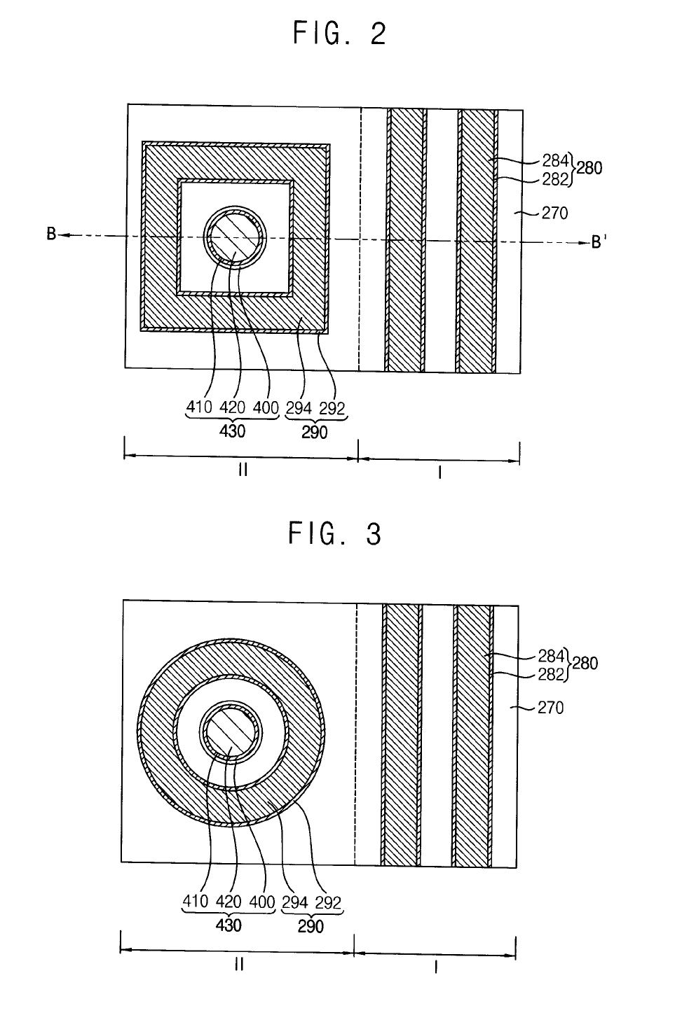

FIG. 1 is a vertical cross-sectional view illustrating a semiconductor device in accordance with some embodiments, and FIGS. 2 to 4 are horizontal cross-sectional views illustrating the semiconductor device. In particular, FIG. 1 is a cross-sectional view cut along a line B-B′ of FIG. 2, and FIGS. 2 to 4 are cross-sectional views, respectively, cut along a line A-A′ of FIG. 1.

Referring to FIGS. 1 and 2, the semiconductor device may include a first low-k dielectric layer structure 310 on a first substrate 100, a first via structure 430 through at least a portion of the first substrate 100 and the first low-k dielectric layer structure 310, and a first blocking layer pattern structure 300 that may be spaced apart from the first via structure 430 in the first low-k dielectric layer structure 310 and surround a sidewall of the first via structure 430.

The semiconductor device may further include circuit elements (not shown), wirings 190, 220, 250, 280, 450, 460, 480 and 490, an insulating interlayer 160, a second low-k dielectric layer structure 500, etc.

The first substrate 100 may be a silicon substrate, a germanium substrate, a silicon-germanium substrate, a silicon on insulator (SOI) substrate, a germanium on insulator (GOI) substrate, or the like.

The first substrate 100 may include a first region I and a second region II. Hereinafter, not only the first and second regions I and II of the first substrate 100 but also spaces extended from the first and second regions I and II of the first substrate 100 upwardly or downwardly may be defined altogether as the first and second regions I and II, respectively. In some embodiments, the first region I may be a circuit region in which circuit elements may be formed, and the second region II may be a via region in which via structures such as the first via structure 430 may be formed. In FIGS. 1 and 2, only one first region I and only one second region II are shown, however, multiple second regions II and multiple first regions I between the second regions II, interleaved first regions I and second regions II, or various other combinations of one or more first region I and one or more second region II may be formed in the semiconductor device. In some embodiments, the semiconductor device may include multiple first via structures 430, and a region in which each first via structure 430 is formed may be defined as the second region II.

In some embodiments, the first region I may include a cell region (not shown) in which memory cells may be formed, a peripheral circuit region (not shown) in which peripheral circuits for driving the memory cells may be formed, and a logic region in which logic devices may be formed. Although memory cells and circuits associated with memory cells have been given as an example, the first region I may include other types of circuits.

An isolation layer 110 including an insulating material, e.g., silicon oxide may be formed on the first substrate 100, and thus a field region on which the isolation layer 110 is formed and an active region on which no isolation layer is formed may be defined in the first substrate 100.

In some embodiments, the semiconductor device may include one or more transistors serving as the circuit element. Here, a single transistor is illustrated as an example. The transistor may include a gate structure 140 having a gate insulation layer pattern 120 and a gate electrode 130 sequentially stacked on the first substrate 100, and a first impurity region 105 at an upper portion of the first substrate 100 adjacent to the gate structure 140. A gate spacer 150 may be further formed on a sidewall of the gate structure 140.

The gate insulation layer pattern 120 may include an oxide, e.g., silicon oxide, a metal oxide, or the like. The gate electrode 130 may include, e.g., doped polysilicon, a metal, a metal nitride, a metal silicide, or the like. The gate spacer 150 may include a nitride, e.g., silicon nitride or other similar materials. The first impurity region 105 may include n-type impurities, e.g., phosphorous, arsenic, or the like, or p-type impurities, e.g., boron, gallium, or the like.

In some embodiments, multiple transistors may be formed in the first region I of the first substrate 100. The circuit elements may not be limited to the transistors, but various types of elements, e.g., diodes, resistors, inductors, capacitors, or the like, may be formed in the first region I. The transistor is merely used as an example.

The circuit elements may be covered by the insulating interlayer 160 on the first substrate 100, and a contact plug 170 contacting the first impurity region 105 may be formed through the insulating interlayer 160. The contact plug 170 may be formed through the insulating interlayer 160 to contact the gate structure 140. The insulating interlayer 160 may include an oxide, e.g., silicon oxide, or other similar materials. The contact plug 170 may include, e.g., a metal, a metal nitride, a metal silicide, doped polysilicon, or the like.

The first low-k dielectric layer structure 310 may be formed on the insulating interlayer 160. The first low-k dielectric layer structure 310 may contain first to fourth wirings 190, 220, 250 and 280 in the first region I, and contain the first blocking layer structure 300 in the second region II.

The first low-k dielectric layer structure 310 may include a low-k dielectric layer in a single level or multiple low-k dielectric layers in multiple levels. FIG. 1 illustrates the first low-k dielectric layer structure 310 including first to fourth low-k dielectric layers 180, 210, 240 and 270 stacked in four levels.

The first to fourth low-k dielectric layers 180, 210, 240 and 270 may include a low-k dielectric material having a dielectric constant lower than that of silicon dioxide (SiO₂), i.e., having a dielectric constant equal to or less than about 3.9. Thus, the first to fourth low-k dielectric layers 180, 210, 240 and 270 may include silicon oxide doped with fluorine or carbon, a porous silicon oxide, spin on organic polymer, or an inorganic polymer, e.g., hydrogen silsesquioxane (HSSQ), methyl silsesquioxane (MSSQ), or other materials with similar properties.

In some embodiments, the first to fourth low-k dielectric layers 180, 210, 240 and 270 may include an ultra low-k dielectric material having a dielectric constant equal to or less than about 2.5, and thus a parasitic capacitance occurring between the first to fourth wirings 190, 220, 250 and 280 may be reduced. As long as the first to fourth low-k dielectric layers 180, 210, 240 and 270 include the low-k dielectric material or the ultra low-k dielectric material, the first to fourth low-k dielectric layers 180, 210, 240 and 270 may not include the same material. Although two different materials having two different ranges of dielectric constants have been used as examples, each of the first to fourth low-k dielectric layers 180, 210, 240 and 270 may be a material with a different dielectric constant from one to all of the other low-k dielectric layers.

The first to fourth wirings 190, 220, 250 and 280 may be formed through the first to fourth low-k dielectric layers 180, 210, 240 and 270, respectively, in the first region I. Thus, the first wiring 190 may be formed through the first low-k dielectric layer 180, and may include a first metal pattern 194 and a first barrier pattern 192 surrounding a sidewall and a bottom of the first metal pattern 194. The second wiring 220 may be formed through the second low-k dielectric layer 210, and may include a third metal pattern 224 and a third barrier pattern 222 surrounding a sidewall and a bottom of the third metal pattern 224. The third wiring 250 may be formed through the third low-k dielectric layer 240, and may include a fifth metal pattern 254 and a fifth barrier pattern 252 surrounding a sidewall and a bottom of the fifth metal pattern 254. The fourth wiring 280 may be formed through the fourth low-k dielectric layer 270, and may include a seventh metal pattern 284 and a seventh barrier pattern 282 surrounding a sidewall and a bottom of the seventh metal pattern 284.

The first to fourth wirings 190, 220, 250 and 280 may have desired shapes and layouts in accordance with the circuit design, and some or all of them may be electrically connected to each other. However, the first wiring 190 may contact the contact plug 170 in the insulating interlayer 160 to be electrically connected to the first impurity region 105 of the first substrate 100.

The first blocking layer pattern structure 300 may include first, second, third and fourth blocking layer patterns 200, 230, 260 and 290 through the first, second, third and fourth low-k dielectric layers 180, 210, 240 and 270, respectively, in the second region II. The levels of the blocking layer patterns included in the first blocking layer pattern structure 300, which may be contained in the low-k dielectric layers, respectively, may be similar to the levels of the low-k dielectric layers included in the first low-k dielectric layer structure 310.

In FIG. 1, the first low-k dielectric layer structure 310 may include the first to fourth low-k dielectric layers 180, 210, 240 and 270. The first blocking layer pattern 200 may be formed through the first low-k dielectric layer 180, and may include a second metal pattern 204 and a second bather pattern 202 surrounding a sidewall and a bottom of the second metal pattern 204. The second blocking layer pattern 230 may be formed through the second low-k dielectric layer 210, and may include a fourth metal pattern 234 and a fourth barrier pattern 232 surrounding a sidewall and a bottom of the fourth metal pattern 234. The third blocking layer pattern 260 may be formed through the third low-k dielectric layer 240, and may include a sixth metal pattern 264 and a sixth barrier pattern 262 surrounding a sidewall and a bottom of the sixth metal pattern 264. The fourth blocking layer pattern 290 may be formed through the fourth low-k dielectric layer 270, and may include an eighth metal pattern 294 and an eighth barrier pattern 292 surrounding a sidewall and a bottom of the eighth metal pattern 294.

Each of the first to fourth blocking layer patterns 200, 230, 260 and 290 may have an annular shape. In an example embodiment, each of the first to fourth blocking layer patterns 200, 230, 260 and 290 may have a rectangular annular shape as shown in FIG. 2. In another example embodiment, each of the first to fourth blocking layer patterns 200, 230, 260 and 290 may have a circular annular shape or an octagonal annular shape, as shown in FIG. 3 and FIG. 4, respectively. The semiconductor device may include the plurality of first via structures 430, and thus multiple first blocking layer pattern structures 300 surrounding the plurality of first via structures 430, respectively, may be formed.

In some embodiments, the first to fourth blocking layer patterns 200, 230, 260 and 290 may directly contact each other. In FIG. 1, the first to fourth blocking layer patterns 200, 230, 260 and 290 are shown to overlap completely in a vertical direction so that the first blocking layer pattern structure 300 may have a vertical sidewall as a whole, however, other embodiments may be different. That is, as long as the first to fourth blocking layer patterns 200, 230, 260 and 290 directly contact each other, the vertical connection structure of the first to fourth blocking layer patterns 200, 230, 260 and 290 may have various configurations.

In some embodiments, the first to fourth blocking layer patterns 200, 230, 260 and 290 may have widths and/or inner diameters different from each other. For example, the first to fourth blocking layer patterns 200, 230, 260 and 290 may have inner diameters gradually decreasing in this order so that the first blocking layer pattern structure 300 may have a horizontal area gradually decreasing from a bottom portion toward a top portion thereof. In other embodiments, the first to fourth blocking layer patterns 200, 230, 260 and 290 may have inner diameters gradually increasing in this order so that the first blocking layer pattern structure 300 may have a horizontal area gradually increasing from the bottom portion toward the top portion thereof. Although two variations between the first to fourth blocking layer patterns 200, 230, 260 and 290 have been used as examples, the first to fourth blocking layer patterns 200, 230, 260 and 290 each make have forms different from or similar to one to all of the other first to fourth blocking layer patterns 200, 230, 260 and 290.

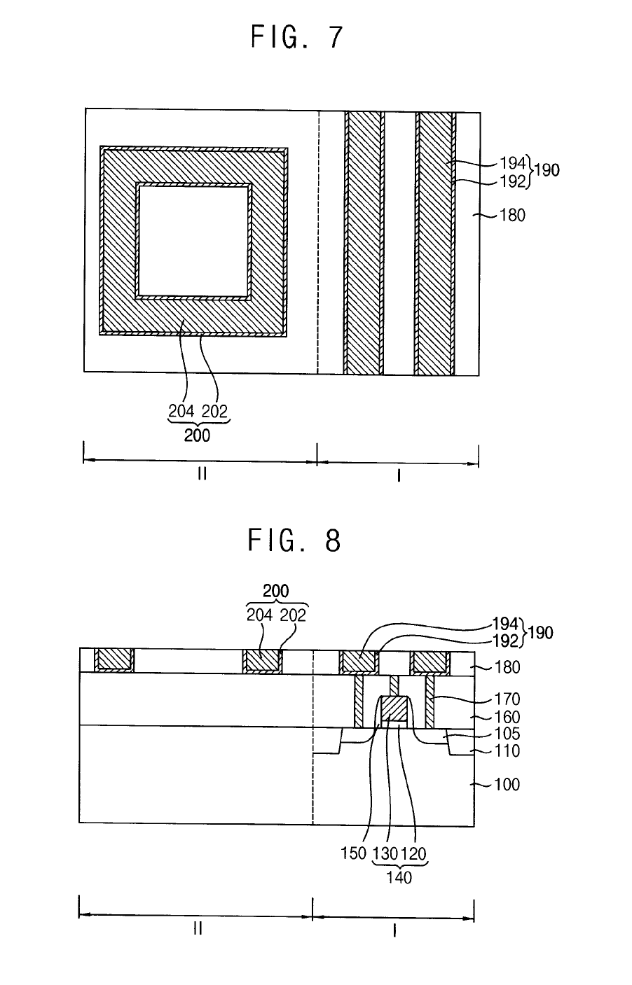

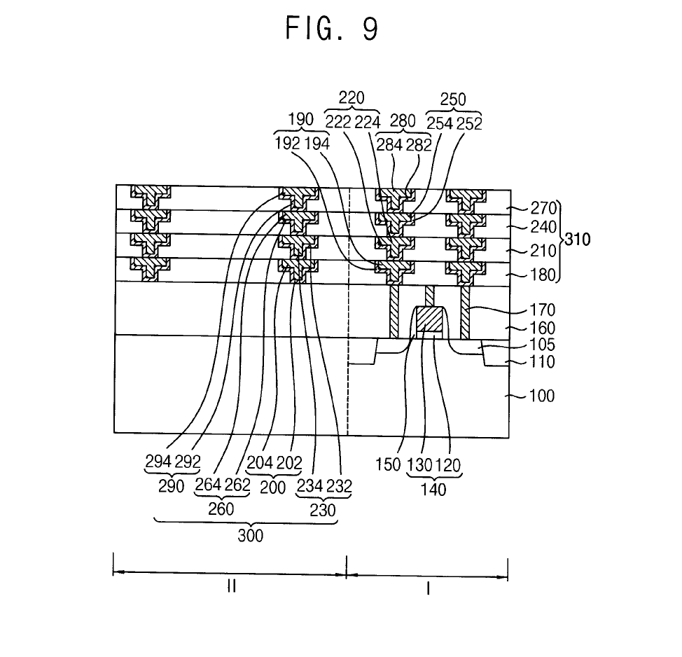

The first to fourth wirings 190, 220, 250 and 280 and the first to fourth blocking layer patterns 200, 230, 260 and 290 may be formed by a double damascene process (refer to FIGS. 6 and 9), and some of them may be formed by a single damascene process (refer to FIG. 8). Alternatively, the first to fourth wirings 190, 220, 250 and 280 and the first to fourth blocking layer patterns 200, 230, 260 and 290 may be formed by forming a metal layer and patterning the metal layer.

In some embodiments, the first wiring 190 and the first blocking layer pattern 200 that may be formed in the first low-k dielectric layer 180 may be formed by a double damascene process or a single damascene process, and the second to fourth wirings 220, 250 and 280 and the second to fourth blocking layer patterns 230, 260 and 290 that may be formed in the second to fourth low-k dielectric layers 210, 240 and 270, respectively, may be formed by a double damascene process.

Thus, when formed by a double damascene process, each of the first to fourth blocking layer patterns 200, 230, 260 and 290 may have a lower portion and an upper portion connected thereto. In this case, a first width T1 of the lower portion may be smaller than a second width T2 of the upper portion, and a first inner diameter D1 of the lower portion may be greater than a second inner diameter D2 of the upper portion (refer to FIG. 6). Although a particular relationship of the widths T1 and T2 and the inner diameters D1 and D2 have been used as examples, the widths T1 and T2 and the inner diameters D1 and D2 may have other relationships. When formed by a single damascene process, each of the first to fourth blocking layer patterns 200, 230, 260 and 290 may include a single pattern having a constant width from a bottom portion toward a top portion thereof. In FIG. 1, the first to fourth wirings 190, 220, 250 and 280 and the first to fourth blocking layer patterns 200, 230, 260 and 290 formed by a double damascene process are shown.

The first to eighth bather patterns 192, 202, 222, 232, 252, 262, 282 and 292 included in the first to fourth wirings 190, 220, 250 and 280 and the first to fourth blocking layer patterns 200, 230, 260 and 290 may include a metal nitride, e.g., titanium nitride, tantalum nitride, tungsten nitride, copper nitride, aluminum nitride, or the like, and the first to eighth metal patterns 194, 204, 224, 234, 254, 264, 284 and 294 may include a metal, e.g., copper, aluminum, tungsten, titanium, tantalum, or the like.

The first via structure 430 may fill a fifth trench 385 through a portion of the first substrate 100, the insulating interlayer 160 and the first low-k dielectric layer structure 310.

In some embodiments, the first via structure 430 may include a first insulation layer pattern 400 and a first barrier layer pattern 410 sequentially stacked on an inner wall of the fifth trench 385, and a via electrode 420 filling a remaining portion of the fifth trench 385 on the first barrier layer pattern 410. That is, a bottom and a sidewall of the via electrode 420 may be surrounded by the first barrier layer pattern 410 and the first insulation layer pattern 400.

The first insulation layer pattern 400 may include an oxide, e.g., silicon oxide or other similar materials, the first barrier layer pattern 410 may include a metal nitride, e.g., titanium nitride, tantalum nitride, tungsten nitride, copper nitride, aluminum nitride, or the like, and the via electrode 420 may include a metal, e.g., copper, aluminum, tungsten, etc., or doped polysilicon, or the like.

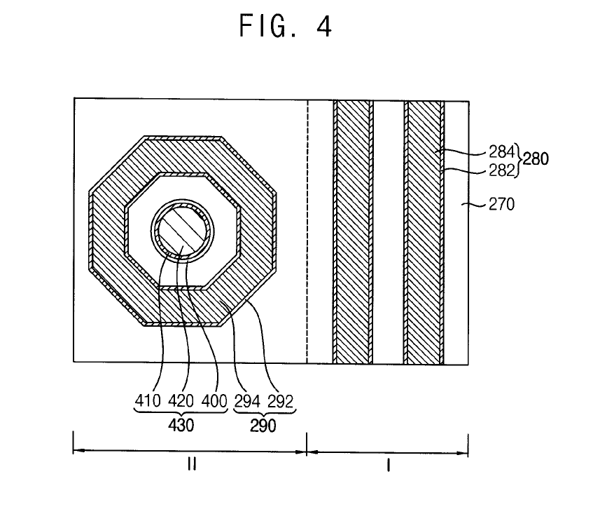

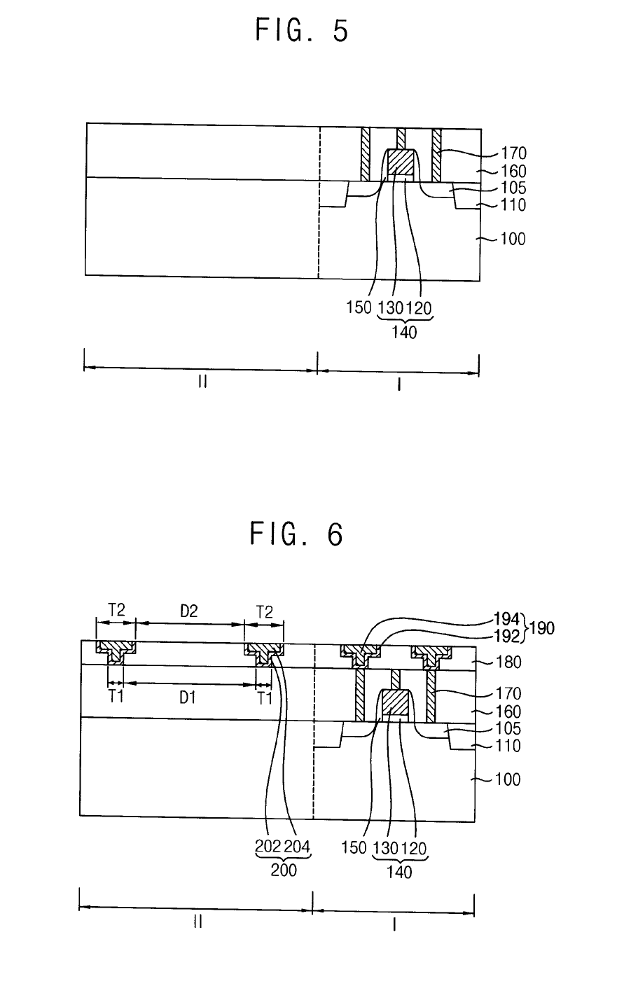

When the fifth trench 385 for forming the first via structure 430 is formed, a portion of the first low-k dielectric layer structure 310 adjacent to the fifth trench 385 may be physically damaged or shocked, however, the damage or shock may be reduced or prevented from propagating toward another portion of the first low-k dielectric layer structure 310 by the first blocking layer pattern structure 300 surrounding a portion of a sidewall of the first via structure 430 in the first low-k dielectric layer structure 310. Additionally, a stress applied to the first low-k dielectric layer structure 310 by the first via structure 430 due to the difference of coefficients of thermal expansion (CTE) of the first via structure 430 and the first low-k dielectric layer structure 310 may be reduced or blocked by the first blocking layer pattern structure 300. The above-mentioned function and effect of the first blocking layer pattern structure 300 may be explained in detail later with reference to FIGS. 5 to 19.

When the multiple first via structures 430 are densely formed, the first blocking layer pattern structure 300 may reduce or remove cross-talk or noise that may be generated by coupling of the multiple first via structures 430. Thus, when circuit elements are formed in the first region I that may be positioned between the second regions II in which the first via structures 430 may be formed, higher design freedom degree may be secured.

The second low-k dielectric layer structure 500 may be formed on the first low-k dielectric layer structure 310, the first blocking layer pattern structure 300, the fourth wirings 280 and the first via structure 430, and may contain the fifth and sixth wirings 450 and 480 in the first region I and seventh and eighth wirings 460 and 490 in the second region II.

In FIG. 1, the second low-k dielectric layer structure 500 includes fifth and sixth low-k dielectric layers 440 and 470 sequentially stacked, however, other embodiments may include different numbers of low-k dielectric layers. That is, the second low-k dielectric layer structure 500 may include a low-k dielectric layer in one level or multiple low-k dielectric layers sequentially stacked.

Each of the fifth and sixth low-k dielectric layers 440 and 470 may include a low-k dielectric material having a dielectric constant equal to or below about 3.9. Thus, each of the fifth and sixth low-k dielectric layers 440 and 470 may include silicon oxide doped with fluorine or carbon, a porous silicon oxide, spin on organic polymer, or an inorganic polymer, e.g., hydrogen silsesquioxane (HSSQ), methyl silsesquioxane (MSSQ), or the like.

In some embodiments, each of the fifth and sixth low-k dielectric layers 440 and 470 may have a dielectric constant higher than those of the first to fourth low-k dielectric layers 180, 210, 240 and 270, and may have a thickness greater than those of the first to fourth low-k dielectric layers 180, 210, 240 and 270.

The fifth to eighth wirings 450, 480, 460 and 490 may be formed by a double damascene process like the first to fourth wirings 190, 220, 250 and 280 and the first to fourth blocking layer patterns 200, 230, 260 and 290, and some of them may be formed by a single damascene process. In FIG. 1, the fifth to eighth wirings 450, 480, 460 and 490 formed by a double damascene process are shown.

In some embodiments, the fifth and seventh wirings 450 and 460 that may be formed in the fifth low-k dielectric layer 440 may be formed by a double damascene process or a single damascene process, and the sixth and eighth wirings 480 and 490 that may be formed in the sixth low-k dielectric layer 470 above the fifth low-k dielectric layer 440 may be formed by a double damascene process.

Thus, the fifth wiring 450 may include a ninth metal pattern 454 and a ninth barrier pattern 452 surrounding a sidewall and a bottom of the ninth metal pattern 454, and the sixth wiring 480 may include an eleventh metal pattern 484 and an eleventh bather pattern 482 surrounding a sidewall and a bottom of the eleventh metal pattern 484. The seventh wiring 460 may include a tenth metal pattern 464 and a tenth barrier pattern 462 surrounding a sidewall and a bottom of the tenth metal pattern 464, and the eighth wiring 490 may include a twelfth metal pattern 494 and a twelfth barrier pattern 492 surrounding a sidewall and a bottom of the twelfth metal pattern 494.

The fifth wiring 450 may be electrically connected to the fourth wiring 480, and some or all of the fifth and sixth wirings 450 and 480 may be electrically connected to each other according to the circuit design.

The seventh wiring 460 may contact a top surface of the first via structure 430, and the eighth wiring 490 may contact a top surface of the seventh wiring 460. Some or all of the seventh wirings 460 and 490 may be electrically connected to some or all of the fifth and sixth wirings 450 and 480.

FIGS. 5, 6, 8 and 9 to 18 are vertical cross-sectional views illustrating stages of a method of manufacturing a semiconductor device in accordance with some embodiments, and FIGS. 7 and 19 are plan views illustrating stages of the method of manufacturing the semiconductor device.

Referring to FIG. 5, circuit elements and a contact plug 170 may be formed on a first substrate 100 having an isolation layer 110 thereon.

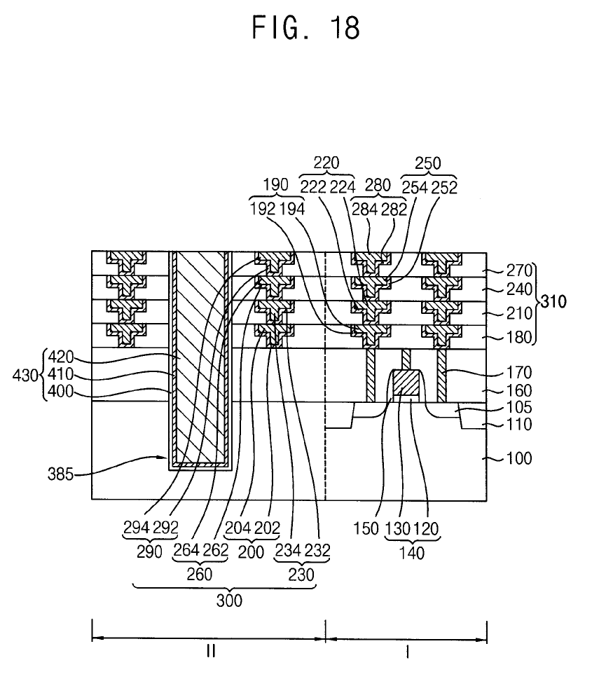

The first substrate 100 may be a silicon substrate, a germanium substrate, a silicon-germanium substrate, a silicon on insulator (SOI) substrate, a germanium on insulator (GOI) substrate, or the like. The first substrate 100 may include a first region I and a second region II, and the first region I may be a circuit region in which the circuit elements may be formed, and the second region II may be a via region in which a first via structure 430 (refer to FIG. 18) may be subsequently formed. In FIG. 5, only one first region I and only one second region II are shown. However, as described above, the semiconductor device may include multiple first via structures 430, multiple second regions II in which the multiple first via structures 430 may be formed may be formed, and multiple first regions I between the second regions II may be formed or various other combinations.

The first region I may include a cell region (not shown) in which memory cells may be formed and a peripheral circuit region (not shown) in which peripheral circuits may be formed, or may include a logic region (not shown) in which logic devices may be formed. As described above, other circuits may be similarly formed.

In some embodiments, the isolation layer 110 may be formed by a shallow trench isolation (STI) process, and include an insulating material, e.g., silicon oxide or the like.

A transistor serving as the circuit element may be formed by a following method.

Particularly, after sequentially forming a gate insulation layer and a gate electrode layer on the first substrate 100 having the isolation layer 110, the gate electrode layer and the gate insulation layer may be patterned by a photolithography process to form a gate structure 140 including a gate insulation layer pattern 120 and a gate electrode 130 on the first substrate 100 in the first region I. The gate insulation layer may be formed to include an oxide, e.g., silicon oxide or a metal oxide, and the gate electrode layer may be formed to include, e.g., doped polysilicon, a metal, a metal nitride and/or a metal silicide.

A gate spacer layer may be formed on the first substrate 100 and the isolation layer 110 to cover the gate structure 140 and may be anisotropically etched to form a gate spacer 150 on a sidewall of the gate structure 140. The gate spacer layer may be formed to include a nitride, e.g., silicon nitride or the like.

Impurities may be implanted into an upper portion of the first substrate 100 to form a first impurity region 105, so that the transistor including the gate structure 140 and the first impurity region 105 may be formed.

In some embodiments, multiple transistors may be formed on the first substrate 100 in the first region I. As described above, the circuit elements may not be limited to the transistor, but various types of circuit elements, e.g., diodes, resistors, inductors, capacitors, etc. may be formed.

An insulating interlayer 160 may be formed on the first substrate 100 to cover the circuit elements, and a contact plug 170 may be formed through the insulating interlayer 160 to contact the first impurity region 105. The contact plug 170 may be formed through the insulating interlayer 160 to contact the gate structure 140.

The insulating interlayer 160 may be formed to include an oxide, e.g., silicon oxide or the like. The contact plug 170 may be formed by forming a contact hole (not shown) through the insulating interlayer 160 to expose the first impurity region 105, forming a conductive layer on the exposed first impurity region 105 and the insulating interlayer 160 to fill the contact hole, and planarizing an upper portion of the conductive layer until a top surface of the insulating interlayer 160 may be exposed. The conductive layer may be formed to include, e.g., a metal, a metal nitride, a metal silicide, doped polysilicon, or the like.

Referring to FIGS. 6 and 7, a first low-k dielectric layer 180 may be formed on the insulating interlayer 160, and at least one first wiring 190 and a first blocking layer pattern 200 may be formed through the first low-k dielectric layer 180 in the first and second regions I and II, respectively.

The first low-k dielectric layer 180 may be formed to include a low-k dielectric material having a dielectric constant lower than that of silicon dioxide (SiO₂), i.e., a dielectric constant equal to or less than about 3.9. For example, the first low-k dielectric layer 180 may be formed to include silicon oxide doped with fluorine or carbon, a porous silicon oxide, spin on organic polymer, or an inorganic polymer, e.g., hydrogen silsesquioxane (HSSQ), methyl silsesquioxane (MSSQ), or the like.

In some embodiments, the first low-k dielectric layer 180 may be formed to include an ultra low-k dielectric material having a dielectric constant equal to or less than about 2.5, and thus a parasitic capacitance occurring between the first wirings 190 may be reduced.

In some embodiments, the first wirings 190 and the first blocking layer pattern 200 may be formed by a double damascene process as follows.

After partially removing the first low-k dielectric layer 180 to form a via hole (not shown) the first low-k dielectric layer 180, which may expose top surfaces of the insulating interlayer 160 and the contact plug 170, an upper portion of the first low-k dielectric layer 180 may be removed to form a first trench (not shown) being in fluid communication with the via hole and having a diameter greater than that of the via hole. Alternatively, after forming the first trench, the via hole may be formed later. A first barrier layer may be formed on inner walls of the via hole and the first trench and the exposed top surfaces of the insulating interlayer 160 and the contact plug 170, and a first metal layer may be formed on the first barrier layer to sufficiently fill remaining portions of the via hole and the first trench. An upper portion of the first barrier layer may be planarized until a top surface of the first low-k dielectric layer 180 may be exposed to form the first wirings 190 contacting the top surface of the contact plug 170 in the first region I and the first blocking layer pattern 200 contacting the top surface of the insulating interlayer 160.

The first barrier layer may be formed to include a metal nitride, e.g., titanium nitride, tantalum nitride, tungsten nitride, copper nitride, aluminum nitride, or the like, and the first metal layer may be formed to include a metal, e.g., copper, aluminum, tungsten, titanium, tantalum, or the like. When the first metal layer is formed using copper or aluminum, a seed layer (not shown) may be formed on the first barrier layer, and the first metal layer may be formed by an electroplating process.

The first wiring 190 may be formed through the first low-k dielectric layer 180, and may include a first metal pattern 194 and a first barrier pattern 192 surrounding a bottom and a sidewall of the first metal pattern 194. The first blocking layer pattern 200 may be formed through the first low-k dielectric layer 180, and may include a second metal pattern 204 and a second barrier pattern 202 surrounding a bottom and a sidewall of the second metal pattern 204.

The first blocking layer pattern 200 may be formed through the first low-k dielectric layer 180 together with the first wirings 190 by the same process, and thus may be easily formed with no additional process.

The first wirings 190 may be formed to have desired shapes and layouts, and the first blocking layer pattern 200 may be formed to have an annular shape when viewed from a top side. For example, the first blocking layer pattern 200 may be formed to have a rectangular annular shape, a circular annular shape, an octagonal annular shape, or the like, and FIG. 7 shows that the first blocking layer pattern 200 has the rectangular annular shape. In some embodiments, the first blocking layer pattern 200 may be formed to surround a portion of a sidewall of a via structure 430 (refer to FIG. 18) subsequently formed, and multiple first blocking layer patterns 200 may be formed according as the semiconductor device may have multiple via structures 430.

As illustrated above, the first blocking layer pattern 200 may be formed by a double damascene process, and thus may be formed to have a lower portion and an upper portion connected thereto. A first width T1 of the lower portion may be smaller than a second width T2 of the upper portion, and a first inner diameter D1 of the lower portion may be greater than a second inner diameter D2 of the upper portion. As described above, the widths and diameters may have different relationships.

Alternatively, referring to FIG. 8, the first wirings 190 and the first blocking layer pattern 200 may be formed by a single damascene process. In this case, the first blocking layer pattern 200 may have a constant width from a bottom portion toward a top portion thereof. Alternatively, the first wirings 190 and the first blocking layer pattern 200 may be formed by forming a metal layer and pattern the metal layer. Hereinafter, for the convenience of explanations, only the case in which the first wirings 190 and the first blocking layer pattern 200 may be formed by a double damascene process as shown in FIG. 6 will be illustrated.

Referring to FIG. 9, second, third and fourth low-k dielectric layers 210, 240 and 270 may be sequentially formed on the first low-k dielectric layer 180, and second, third and fourth wirings 220, 250 and 280 and second, third and fourth blocking layer patterns 230, 260 and 290 may be formed in the second, third and fourth low-k dielectric layers 210, 240 and 270, respectively.

That is, the second wirings 220 and the second blocking layer pattern 230 may be formed through the second low-k dielectric layer 210, the third wirings 250 and the third blocking layer pattern 260 may be formed through the third low-k dielectric layer 240, and the fourth wirings 280 and the fourth blocking layer pattern 290 may be formed through the fourth low-k dielectric layer 270. Each of the second to fourth wirings 220, 250 and 280 and each of the second to fourth blocking layer patterns 230, 260 and 290 may be formed by a damascene process substantially the same as or similar to the damascene process for forming the first wirings 190 and the first blocking layer pattern 200; however in other embodiments, different damascene processes may be used for one or more of the first to fourth wirings 190, 220, 250 and 280.

Thus, the second wiring 220 may be formed to include a third metal pattern 224 and a third barrier pattern 222, the third wiring 250 may be formed to include a fifth metal pattern 254 and a fifth bather pattern 252, and the fourth wiring 280 may be formed to include a seventh metal pattern 284 and a seventh barrier pattern 282. Additionally, the second blocking layer pattern 230 may be formed to include a fourth metal pattern 234 and a fourth barrier pattern 232, the third blocking layer pattern 260 may be formed to include a sixth metal pattern 264 and a sixth barrier pattern 262, and the fourth blocking layer pattern 290 may be formed to include an eighth metal pattern 294 and an eighth barrier pattern 292.

Some or all of the first to fourth wirings 190, 220, 250 and 280 may be formed to be electrically connected to each other in accordance with the circuit design.

The first to fourth blocking layer patterns 200, 230, 260 and 290 may be formed to directly contact each other so that a first blocking layer pattern structure 300 may be formed. In FIG. 9, the first to fourth blocking layer patterns 200, 230, 260 and 290 overlap completely in a vertical direction so that the first blocking layer pattern structure 300 may have a vertical sidewall as a whole, however, embodiments are not limited to such a configuration. That is, as long as the first to fourth blocking layer patterns 200, 230, 260 and 290 directly contact each other, the vertical connection structure may have a different configuration.

Thus, the first to fourth blocking layer patterns 200, 230, 260 and 290 may have widths and/or inner diameters different from each other. For example, the first to fourth blocking layer patterns 200, 230, 260 and 290 may have inner diameters gradually decreasing in this order so that the first blocking layer pattern structure 300 may have a horizontal area gradually decreasing from a bottom portion toward a top portion thereof. In other embodiments, the first to fourth blocking layer patterns 200, 230, 260 and 290 may have inner diameters gradually increasing in this order so that the first blocking layer pattern structure 300 may have a horizontal area gradually increasing from the bottom portion toward the top portion thereof. As described above, the first to fourth blocking layer patterns 200, 230, 260 and 290 may have other configurations.

In FIG. 9, a first low-k dielectric layer structure 310 including the first to fourth low-k dielectric layers 180, 210, 240 and 270 in four levels is shown, however, other numbers of levels may be present in other embodiments. That is, the first low-k dielectric layer structure 310 may include one low-k dielectric layer in one level or multiple low-k dielectric layers in multiple levels. Further, as long as the low-k dielectric layers include a low-k dielectric material or an ultra low-k dielectric material, they may not include the same material. The levels of the blocking layer patterns included in the first blocking layer pattern structure 300 may be similarly changed as the levels of the low-k dielectric layers included in the first low-k dielectric layer structure 310.

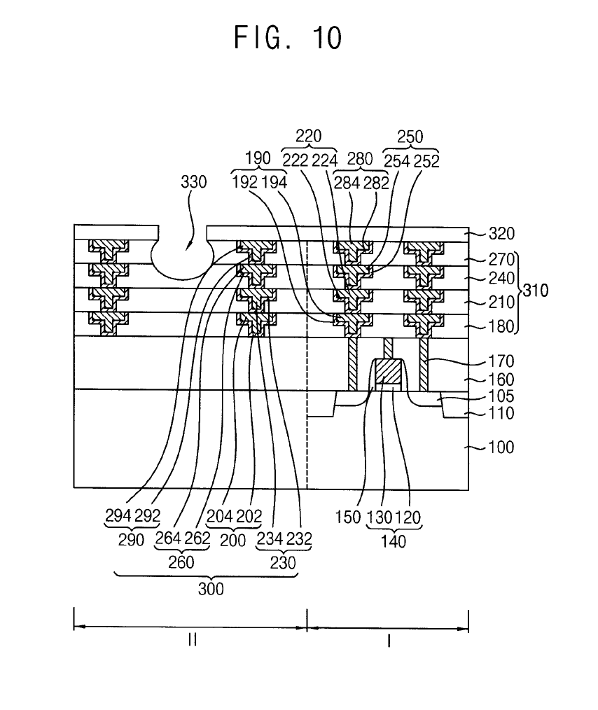

Referring to FIG. 10, a photoresist pattern 320 exposing a portion of the first low-k dielectric layer structure 310 in the second region II may be formed on the first low-k dielectric layer structure 310, the first blocking layer pattern structure 300 and the fourth wirings 280, and the exposed portion of the first low-k dielectric layer structure 310 may be etched using the photoresist pattern 320 as an etching mask. Particularly, the photoresist pattern 320 may expose a portion of the first low-k dielectric layer structure 310 inside of the annular shape of the first blocking layer pattern structure 300.

In some embodiments, the etching process may be performed using plasma including fluorine, and the first low-k dielectric layer structure 310 may be isotropically etched. Thus, a second trench 330 having a spherical shape may be formed in the first low-k dielectric layer structure 310.

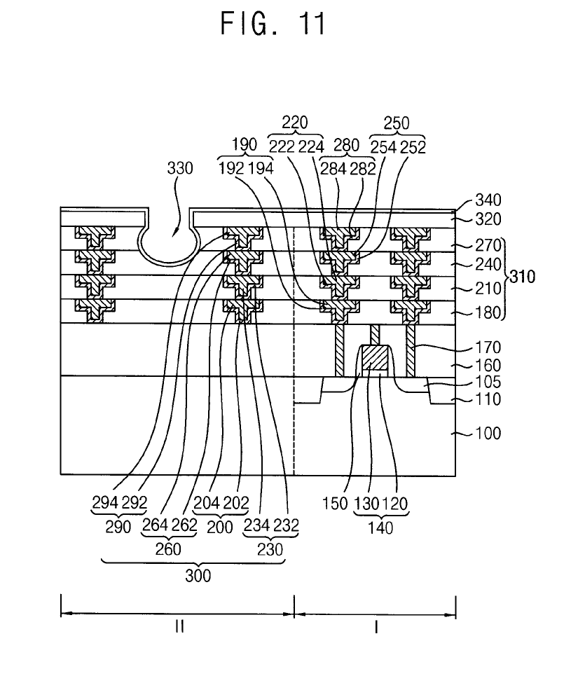

Referring to FIG. 11, a first protection layer 340 may be formed on the photoresist pattern 320 and an inner wall of the second trench 330. The first protection layer 340 may be formed to include, e.g., polymer.

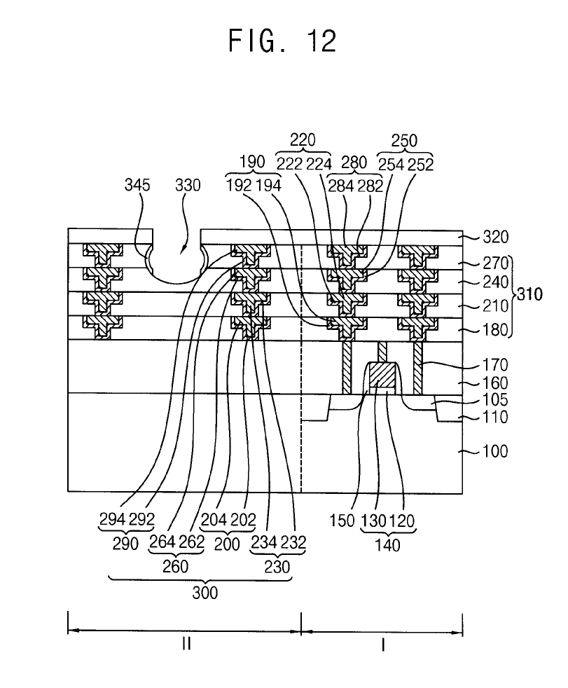

Referring to FIG. 12, the first protection layer 340 may be etched to form a first protection layer pattern 345.

In some embodiments, the first protection layer 340 may be anisotropically etched using an ion collision process. Thus, the first protection layer pattern 345 may be formed substantially only on a sidewall of the second trench 330, and a bottom of the second trench 330 may be exposed.

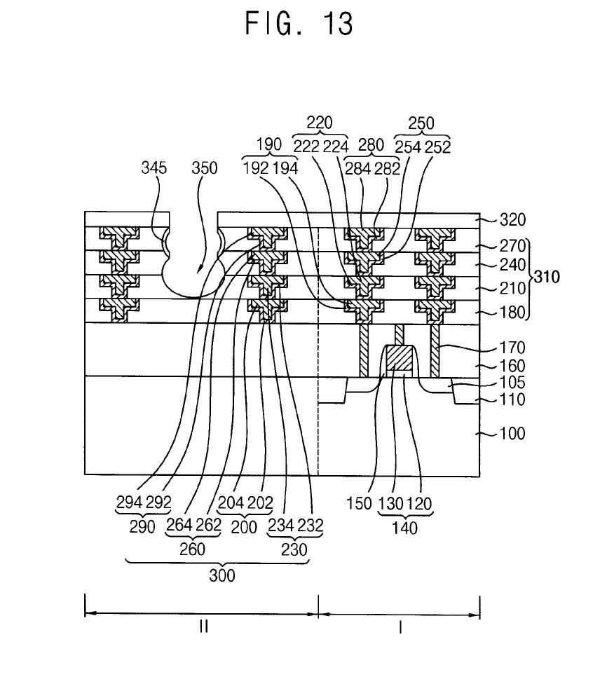

Referring to FIG. 13, like the process illustrated with reference to FIG. 10, a portion of the first low-k dielectric layer structure 310 under the exposed bottom of the second trench 330 may be etched using the photoresist pattern 320 and the first protection layer pattern 345 as an etching mask. Thus, the second trench 330 may be expanded vertically to form a third trench 350 in the first low-k dielectric layer structure 310.

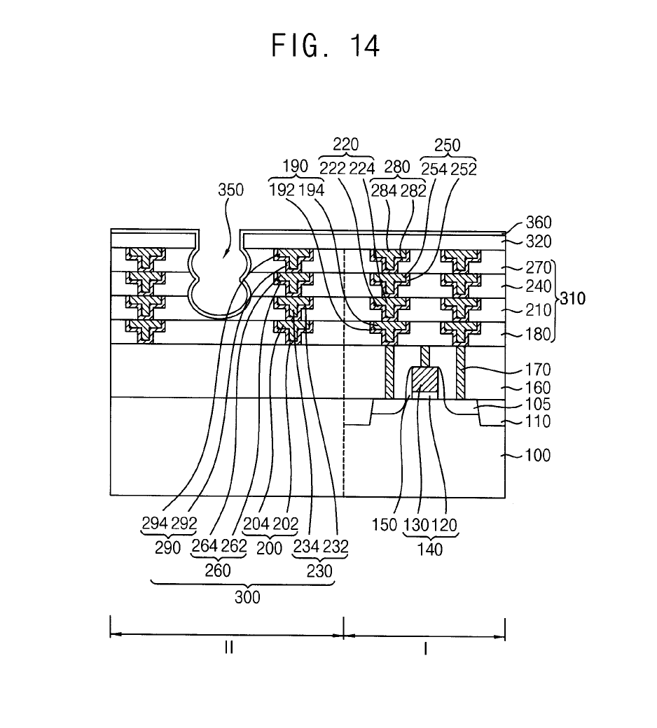

Referring to FIG. 14, like the process illustrated with reference to FIG. 11, a second protection layer 360 may be formed on the photoresist pattern 320, an inner wall of the third trench 350, and the first protection layer pattern 345. The second protection layer 360 may be formed using substantially the same material as that of the first protection layer 340, so that the first protection layer pattern 345 may be merged into the second protection layer 360.

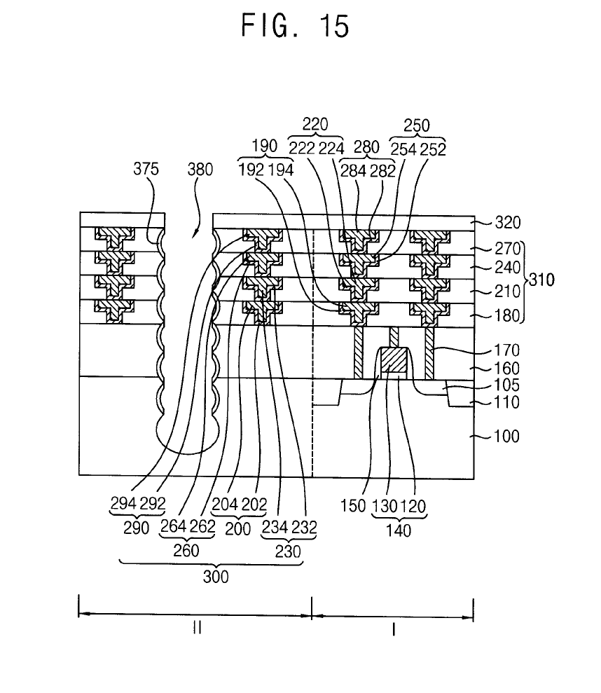

Referring to FIG. 15, processes illustrated with reference to FIGS. 12 to 14 may be repeatedly performed. Thus, a fourth trench 380 may be formed through the first low-k dielectric layer structure 310, the insulating interlayer 160 and a portion of the first substrate 100. The fourth trench 380 may extend in a vertical direction; however, a sidewall of the fourth trench 380 may have a shape in which multiple scallops are vertically connected to each other. A third protection layer pattern 375 may remain on a portion of the sidewall of the fourth trench 380.

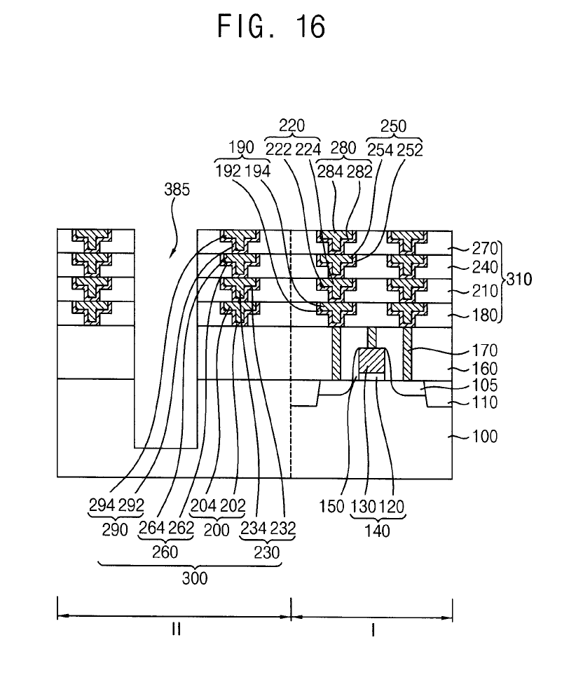

Referring to FIG. 16, after removing the photoresist pattern 320, a cleaning process may be performed using a chemical so that the fourth trench 380 may have a smooth sidewall and the third protection layer pattern 375 remaining on the sidewall of the fourth trench 380 may be removed. Thus, a fifth trench 385 having a vertical sidewall may be formed through the first low-k dielectric layer structure 310, the insulating interlayer 160 and a portion of the first substrate 100.

The chemical used for the cleaning process may damage the first low-k dielectric layer structure 310 including the low-k dielectric material or the ultra low-k dielectric material. Additionally, the first low-k dielectric layer structure 310 may have a stacked structure in which multiple low-k dielectric layers 180, 210, 240 and 270 are sequentially stacked, so that exfoliation may occur at interfaces between the multiple low-k dielectric layers 180, 210, 240 and 270.

However, in some embodiments, a portion of the first low-k dielectric layer structure 310 at which the fifth trench 385 is formed may be surrounded by the first blocking layer pattern structure 300. Thus, even the first low-k dielectric layer structure 310 is partially damaged due to the chemical in the cleaning process, crack generation or exfoliation may be prevented at other portions of the first low-k dielectric layer structure 310, especially at a portion of the first low-k dielectric layer structure 310 in the first region I at which the first to fourth wirings 190, 220, 250 and 280 may be formed. That is, the first blocking layer pattern structure 300 may prevent the physical damage of a portion of the first low-k dielectric layer structure 310 due to the cleaning process from propagating to other portions thereof.

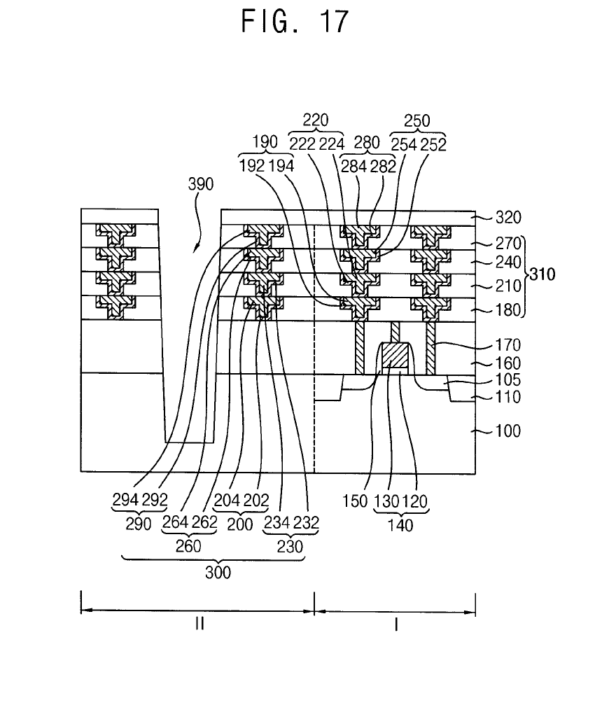

FIGS. 10 to 16 show stages of a Bosch method for forming the fifth trench 385 having a smooth sidewall substantially perpendicular to the top surface of the first substrate 100 to have a constant diameter along the whole depth. Alternatively, a sixth trench 390 may be formed by a non-Bosch method instead of the fifth trench 385, which may be shown in FIG. 17.

Referring to FIG. 17, a photoresist pattern 320 partially exposing a portion of the first low-k dielectric layer structure 310 inside of the annular shape of the first blocking layer structure 300 may be formed on the first low-k dielectric layer structure 310, the first blocking layer structure 300 and the fourth wirings 280, and the exposed first low-k dielectric layer structure 310, and the insulating interlayer 160 and a portion of the first substrate 100 thereunder may be dry etched using the photoresist pattern 320 as an etching mask.

In some embodiments, the dry etching process may be performed by laser drilling or by anisotropic plasma etching, so that the first low-k dielectric layer structure 310, and the insulating interlayer 160 and the portion of the first substrate 100 thereunder may be anisotropically etched. Thus, the sixth trench 390 may be formed to have a smooth sidewall that may gradually decrease from a top portion toward a bottom portion thereof.

Even with the above dry etching process, a portion of the first low-k dielectric layer structure 310 at which the sixth trench 390 may be formed may be physically damaged, however, in some embodiments, the physical damage may be reduced or prevented from propagating to other portions of the first low-k dielectric layer structure 310 by the first blocking layer pattern structure 300.

Referring to FIGS. 18 and 19, the first via structure 430 may be formed to fill the fifth trench 385.

Particularly, an insulation layer and a barrier layer may be sequentially formed on an inner wall of the fifth trench 385, the first low-k dielectric layer structure 310, the first blocking layer pattern 300 and the fourth wirings 280, and an electrode layer may be formed on the barrier layer to sufficiently fill the fifth trench 385. The insulation layer may be formed to include an oxide, e.g., silicon oxide, the barrier layer may be formed to include a metal nitride, e.g., titanium nitride, tantalum nitride, tungsten nitride, copper nitride, aluminum nitride, or the like, and the electrode layer may be formed to include a metal, e.g., copper, aluminum, tungsten, or the like, or doped polysilicon or other similar materials. When the metal layer is formed using copper or aluminum, a seed layer (not shown) may be formed on the barrier layer, and the electrode layer may be formed by an electroplating process.

The electrode layer, the barrier layer and the insulation layer may be planarized until a top surface of the first low-k dielectric layer structure 310 may be exposed to form the first via structure 430 filling the fifth trench 385. A portion of a sidewall of the first via structure 430 may be surrounded by the first blocking layer pattern structure 300. The first via structure 430 may include a first insulation layer pattern 400, a first barrier layer pattern 410 and a via electrode 420.

Referring to FIG. 1 again, a second low-k dielectric layer structure 500 may be formed on the first low-k dielectric layer structure 310, the first blocking layer pattern structure 300, the fourth wirings 280 and the first via structure 430 to manufacture the semiconductor device. Fifth and sixth wirings 450 and 480 may be formed in the second low-k dielectric layer structure 500 in the first region I, and seventh and eighth wirings 460 and 490 may be formed in the second low-k dielectric layer structure 500 in the second region II.

FIG. 1 shows the second low-k dielectric layer structure 500 including the fifth and sixth low-k dielectric layers 440 and 470 sequentially stacked, however, other embodiments may include different numbers of layers. That is, the second low-k dielectric layer structure 500 may include one low-k dielectric layer in one level or multiple low-k dielectric layers sequentially stacked in multiple levels.

Each of the fifth and sixth low-k dielectric layers 440 and 470 may be formed to include a low-k dielectric material having a dielectric constant lower than that of silicon dioxide (SiO₂), i.e., a dielectric constant equal to or less than about 3.9. Thus, the fifth and sixth low-k dielectric layers 440 and 470 may be formed to include silicon oxide doped with fluorine or carbon, a porous silicon oxide, spin on organic polymer, or an inorganic polymer, e.g., hydrogen silsesquioxane (HSSQ), methyl silsesquioxane (MSSQ), or the like.

In some embodiments, each of the fifth and sixth low-k dielectric layers 440 and 470 may have a dielectric constant higher than those of the first to fourth low-k dielectric layers 180, 210, 240 and 270, and may have a thickness greater than those of the first to fourth low-k dielectric layers 180, 210, 240 and 270.

The fifth to eighth wirings 450, 480, 460 and 490 may be formed by a double damascene process like the first to fourth wirings 190, 220, 250 and 280 and the first to fourth blocking layer patterns 200, 230, 260 and 290, and some of them may be formed by a single damascene process. FIG. 1 shows the fifth to eighth wirings 450, 480, 460 and 490 formed by a double damascene process.

In some embodiments, the fifth and seventh wirings 450 and 460 that may be formed in the fifth low-k dielectric layer 440 may be formed by a double damascene process or a single damascene process, and the sixth and eighth wirings 480 and 490 that may be formed in the sixth low-k dielectric layer 470 above the fifth low-k dielectric layer 440 may be formed by a double damascene process. However, in other embodiments the processes used to form the fifth, sixth, seventh, and eighth wirings 460, 480, 460, and 490 may be different.

Thus, the fifth wiring 450 may include a ninth metal pattern 454 and a ninth bather pattern 452 surrounding a sidewall and a bottom of the ninth metal pattern 454, and the sixth wiring 480 may include an eleventh metal pattern 484 and an eleventh barrier pattern 482 surrounding a sidewall and a bottom of the eleventh metal pattern 484. The seventh wiring 460 may include a tenth metal pattern 464 and a tenth barrier pattern 462 surrounding a sidewall and a bottom of the tenth metal pattern 464, and the eighth wiring 490 may include a twelfth metal pattern 494 and a twelfth barrier pattern 492 surrounding a sidewall and a bottom of the twelfth metal pattern 494.

Some or all of the first to sixth wirings 190, 220, 250, 280, 450 and 480 may be formed to be electrically connected to each other according to the circuit design. The seventh wiring 460 may be formed to contact a top surface of the first via structure 430, and the eighth wiring 490 may be formed to contact a top surface of the seventh wiring 460. Some or all of the seventh wirings 460 and 490 may be electrically connected to some or all of the fifth and sixth wirings 450 and 480.

The process for forming the second low-k dielectric layer structure 500 or the process for forming the fifth and sixth wirings 450 and 480 and the seventh and eighth wirings 460 and 490 may require high temperature, and thus the first low-k dielectric layer structure 310 may be stressed to be damaged due to the difference of CTE between the first via structure 430 and the first low-k dielectric layer structure 310 that have been already formed under the second low-k dielectric layer structure 500 or the fifth and sixth wirings 450 and 480 and the seventh and eighth wirings 460 and 490. However, in some embodiments, the first blocking layer pattern structure 300 may surround a portion of the first via structure 430 through the first low-k dielectric layer structure 310, so that the stress applied by the first via structure 430 onto the first low-k dielectric layer structure 310 may be reduced or blocked. Thus, the first low-k dielectric layer structure 310 may have increased reliability.

As illustrated above, in some embodiments, when the fifth trench 385 or the sixth trench 390 for forming the first via structure 430 is formed, the physical damage or shock to a portion of the first low-k dielectric layer structure 310 adjacent thereto may be reduced or prevented from propagating to other portions of the first low-k dielectric layer structure 310 by the first blocking layer pattern structure 300. Additionally, the first blocking layer pattern structure 300 may reduce or block the stress by the first via structure 430 onto the first low-k dielectric layer structure 310 due to the difference of CTE between the first via structure 430 and the first low-k dielectric layer structure 310.

Furthermore, when multiple first via structures 430 is densely formed, the first blocking layer pattern structure 300 may reduce or remove cross-talk or noise that may be generated by coupling of the multiple first via structures 430. Thus, when circuit elements are formed in the first region I that may be positioned between the second regions II in which the first via structures 430 may be formed, higher design freedom degree may be secured.

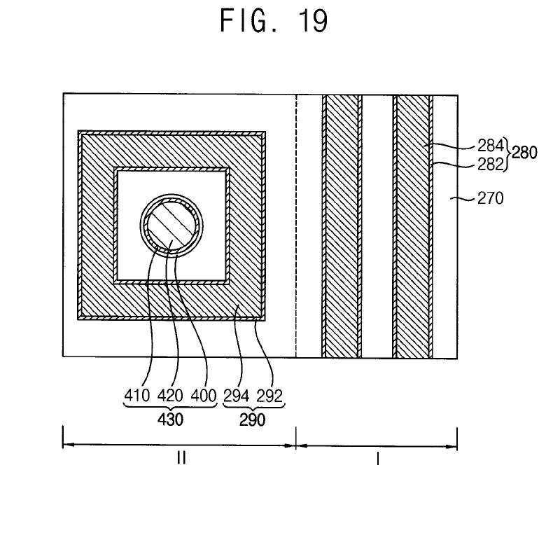

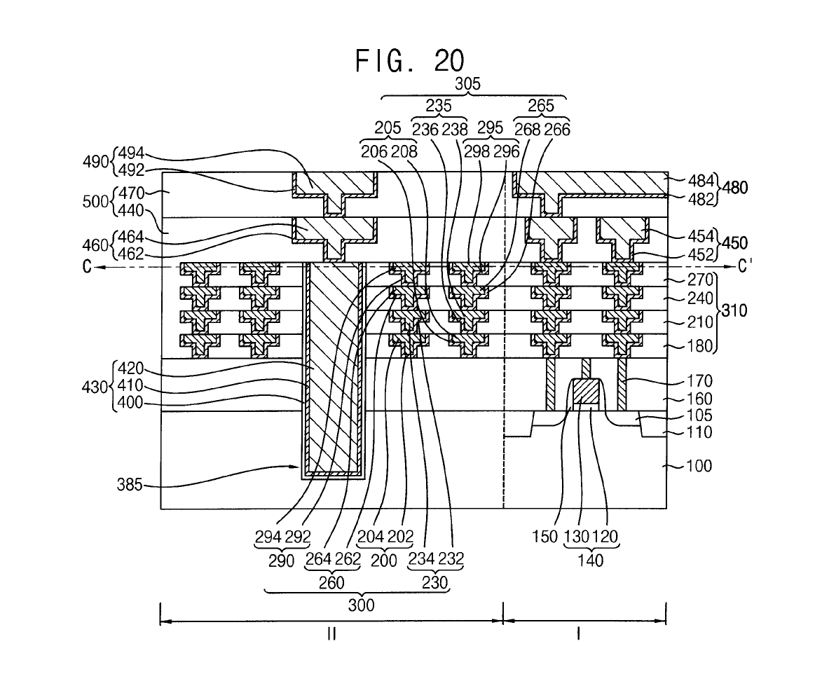

FIG. 20 is a vertical cross-sectional view illustrating a semiconductor device in accordance with some embodiments, and FIG. 21 is a horizontal cross-sectional view illustrating the semiconductor device. Particularly, FIG. 20 is a cross-sectional view cut along a line D-D′ of FIG. 21, and FIG. 21 is a cross-sectional view cut along a line C-C′ of FIG. 20. The semiconductor device may be substantially the same as or similar to that of FIGS. 1 and 2, except for a second blocking layer pattern structure 305. Thus, like reference numerals refer to like elements, and detailed descriptions thereon are omitted herein.

Referring to FIGS. 20 and 21, the semiconductor device may include a first low-k dielectric layer structure 310 on a first substrate 100, a first via structure 430 through at least a portion of the first substrate 100 and the first low-k dielectric layer structure 310, and first and second blocking layer pattern structures 300 and 305 that may be spaced apart from the first via structure 430 in the first low-k dielectric layer structure 310 and surround a sidewall of the first via structure 430.

The semiconductor device may further include circuit elements (not shown), wirings 190, 220, 250, 280, 450, 480, 460 and 490, an insulating interlayer 160, a second low-k dielectric layer 500, etc.

The second blocking layer pattern structure 305 may include fifth, sixth, seventh and eighth blocking layer patterns 205, 235, 265 and 295 through the first, second, third and fourth low-k dielectric layers 180, 210, 240 and 270, respectively, in the second region II. The levels of the blocking layer patterns included in the second blocking layer pattern structure 305 may be changed similar to the levels of the low-k dielectric layers included in the first low-k dielectric layer structure 310.

Further, the second blocking layer pattern structure 305 may not be formed in all of the low-k dielectric layers included in the first low-k dielectric layer structure 310. That is, the second blocking layer pattern structure 305 may include blocking layer patterns in some or all of the first to fourth low-k dielectric layers 180, 210, 240 and 270. FIG. 20 shows the second blocking layer pattern structure 305 including the fifth to eighth blocking layer patterns 205, 235, 265 and 295 in the first to fourth low-k dielectric layers 180, 210, 240 and 270, respectively.

Thus, the fifth blocking layer pattern 205 may be formed through the first low-k dielectric layer 180, and may include a thirteenth metal pattern 208 and a thirteenth barrier pattern 206 surrounding a sidewall and a bottom of the thirteenth metal pattern 208. The sixth blocking layer pattern 235 may be formed through the second low-k dielectric layer 210, and may include a fourteenth metal pattern 238 and a fourteenth barrier pattern 236 surrounding a sidewall and a bottom of the fourteenth metal pattern 238. The seventh blocking layer pattern 265 may be formed through the third low-k dielectric layer 240, and may include a fifteenth metal pattern 268 and a fifteenth barrier pattern 266 surrounding a sidewall and a bottom of the fifteenth metal pattern 268. The eighth blocking layer pattern 295 may be formed through the fourth low-k dielectric layer 270, and may include a sixteenth metal pattern 298 and an sixteenth barrier pattern 296 surrounding a sidewall and a bottom of the sixteenth metal pattern 298.

The fifth to eighth blocking layer patterns 205, 235, 265 and 295 forming the second blocking layer pattern structure 305 may include substantially the same shapes and materials as those of the first to fourth blocking layer patterns 200, 230, 260 and 290. The second blocking layer pattern structure 305 may be spaced apart from the first blocking layer structure 300, and may be more distant than the first blocking layer pattern structure 300 from the first via structure 430. Even if each of the first to fourth blocking layer patterns 200, 230, 260 and 290 forming the first blocking layer pattern structure 300 may have a particular shape or shapes, e.g., a rectangular annular shape, each of the fifth to eighth blocking layer patterns 205, 235, 265 and 295 forming the second blocking layer pattern structure 305 may have the same, similar, or other shapes, e.g., a circular annular shape.

The semiconductor device may further include the second blocking layer pattern structure 305 in addition to the first blocking layer pattern structure 300, so that the effect of reducing or blocking the physical damage or stress may be increased. Additionally, the effect of reducing or preventing the cross-talk or noise due to the coupling of the multiple first via structures 430 may be increased.

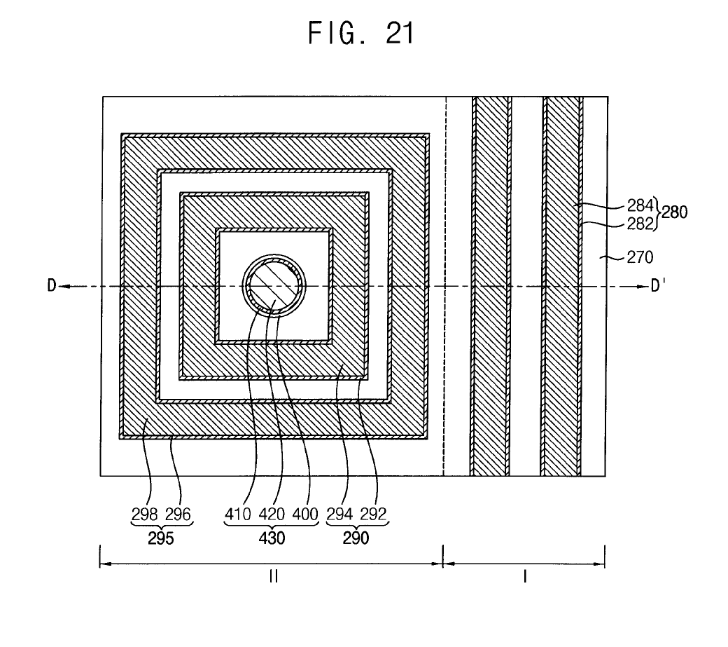

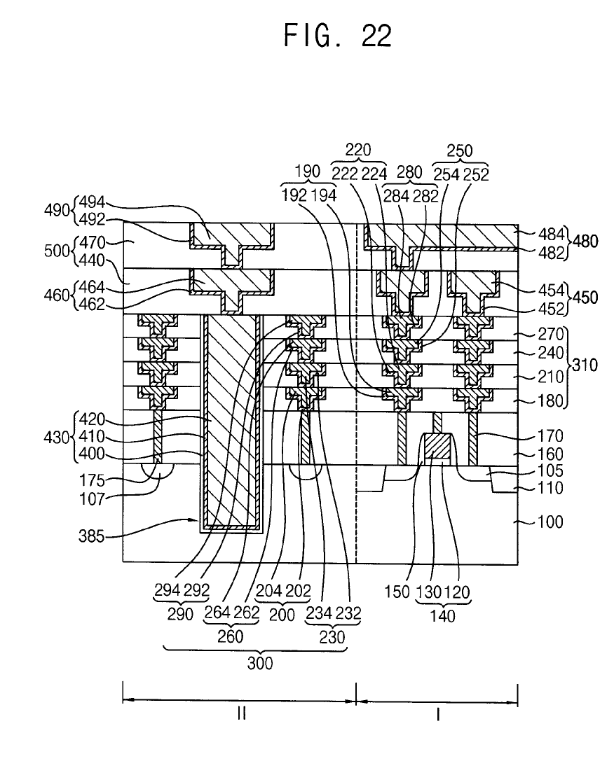

FIG. 22 is a vertical cross-sectional view illustrating a semiconductor device in accordance with some embodiments. The semiconductor device may be substantially the same as or similar to that of FIGS. 1 and 2, except for a ground wiring 175 and a second impurity region 107. Thus, like reference numerals refer to like elements, and detailed descriptions thereon are omitted herein.

Referring to FIG. 22, the semiconductor device may include an insulating interlayer 160 and a first low-k dielectric layer structure 310 sequentially stacked on a first substrate 100, a first via structure 430 through at least a portion of the first substrate 100, the insulating interlayer 160 and the first low-k dielectric layer structure 310, a first blocking layer pattern structure 300 that may be spaced apart from the first via structure 430 in the first low-k dielectric layer structure 310 and surround a sidewall of the first via structure 430, and the ground wiring 175 that may be formed through the insulating interlayer 160 and electrically connected to the first blocking layer pattern structure 300.

The semiconductor device may further include circuit elements (not shown), wirings 190, 220, 250, 280, 450, 480, 460 and 490, a second low-k dielectric layer structure 500, etc.

The second impurity region 107 may be formed at an upper portion of the first substrate 100 in the second region II to overlap the first blocking layer pattern structure 300. The second impurity region 107 may be doped with n-type impurities, e.g., phosphorous, arsenic, or the like, or p-type impurities, e.g., boron, gallium, or the like.

The ground wiring 175 may be formed through the insulating interlayer 160 to contact a top surface of the second impurity region 107 and a bottom of the first blocking layer pattern structure 300. Thus, a signal due to the coupling between the first via structures 430 blocked by the first blocking layer pattern structure 300 may be transferred to the second impurity region 107 of the first substrate 100 to be grounded. Accordingly, the effect of reducing or preventing the cross-talk or noise due to the coupling between the first via structures 430 may be increased.

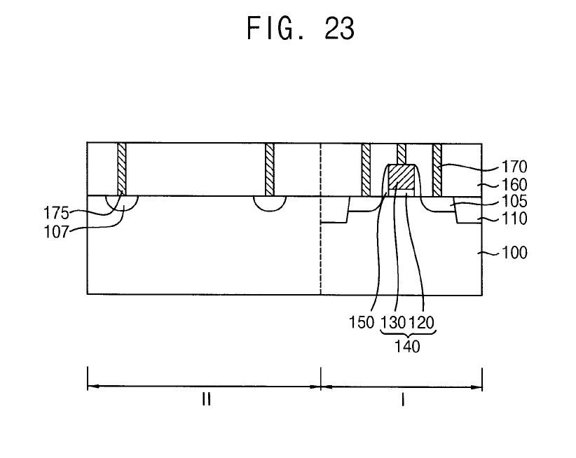

FIG. 23 is a cross-sectional view illustrating a stage of a method of manufacturing a semiconductor device in accordance with some embodiments. This method may include processes substantially the same as or similar to those illustrated with reference to FIGS. 5 to 19, and thus like reference numerals refer to like elements, and detailed descriptions thereon are omitted herein.

Referring to FIG. 23, a process substantially the same as or similar to that illustrated with reference to FIG. 5 may be performed.

That is, a gate structure 140 and a gate spacer 150 may be formed on a first substrate 100 having an isolation layer 110 thereon, and a first impurity region 105 may be formed.

A second impurity region 107 may be formed at an upper portion of the first substrate 100 in the second region II by an ion implantation process. The second impurity region 107 may be formed before or simultaneously with the first impurity region 105.

When a contact plug 170 is formed in the first region I, a ground wiring 175 may be formed to contact a top surface of the second impurity region 107 in the second region II.

In some embodiments, the ground wiring 175 may be formed using a material substantially the same as that of the contact plug 170.

Referring to FIG. 22 again, processes substantially the same as or similar to those illustrated with reference to FIGS. 6 to 19 and 1 and 2 may be performed to manufacture the semiconductor device. In this case, the first blocking layer pattern 200 may be formed to contact a top surface of the ground wiring 175.

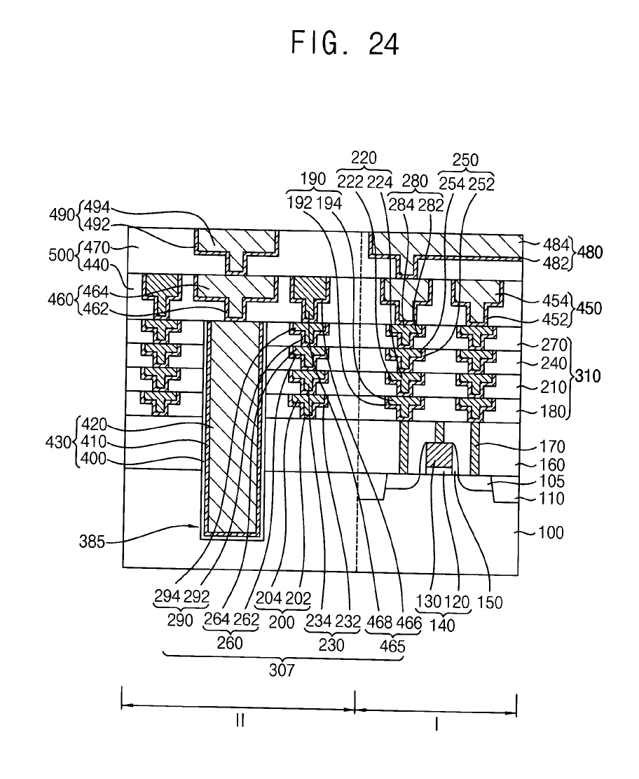

FIG. 24 is a vertical cross-sectional view illustrating a semiconductor device in accordance with some embodiments. The semiconductor device may be substantially the same as or similar to that of FIGS. 1 and 2, except that the semiconductor device may include a third blocking layer pattern structure 307 instead of the first blocking layer pattern structure 300. Thus, like reference numerals refer to like elements, and detailed descriptions thereon are omitted herein.

Referring to FIG. 24, the semiconductor device may include first and second low-k dielectric layer structures 310 and 500 sequentially stacked on a first substrate 100, a first via structure 430 through at least a portion of the first substrate 100 and the first low-k dielectric layer structure 310, seventh and eighth wirings 460 and 490 in the second low-k dielectric layer structure 500 on the first via structure 430, and a third blocking layer pattern structure 307 that may be spaced apart from the first via structure 430 and the seventh wiring 460 in the first and second low-k dielectric layer structures 310 and 500 and surround sidewalls of the first via structure 430 and the seventh wiring 460.

The semiconductor device may further include circuit elements (not shown), first to sixth wirings 190, 220, 250, 280, 450 and 480, an insulating interlayer 160, as described above.

The third blocking layer pattern structure 307 may further include a ninth blocking layer pattern 465 in the second low-k dielectric layer structure 500 in addition to the first to fourth blocking layer patterns 200, 230, 260 and 290 in the first low-k dielectric layer structure 310.

The ninth blocking layer pattern 465 may contact a top surface of the fourth blocking layer pattern 290, and include a seventeenth metal pattern 468 and a seventeenth barrier pattern 466 surrounding a bottom and a sidewall of the seventeenth metal pattern 468. The ninth blocking layer pattern 465 may have an annular shape like the first to fourth blocking layer patterns 200, 230, 260 and 290.

The ninth blocking layer pattern 465 may surround a sidewall of the seventh wiring 460 through a fifth low-k dielectric layer 440, which may be at a lower portion of the second low-k dielectric layer structure 500, on a top surface of the first via structure 430. Thus, the third blocking layer pattern structure 307 may prevent or reduce the cross-talk or noise due to the coupling of the multiple first via structures 430 as well as the coupling of the seventh wirings 460 on the first via structures 430.

For the electrical connection between the first via structure 430 and the first to sixth wirings 190, 220, 250, 280, 450 and 480, the third blocking layer pattern structure 307 may not be formed in a sixth low-k dielectric layer 470, which may be at an upper portion of the second low-k dielectric layer structure 500. In other embodiments, if the second low-k dielectric layer structure 500 includes three or more low-k dielectric layers, structures similar to the ninth blocking layer pattern 465 may be formed in each of the low-k dielectric layers except for an uppermost low-k dielectric layer.

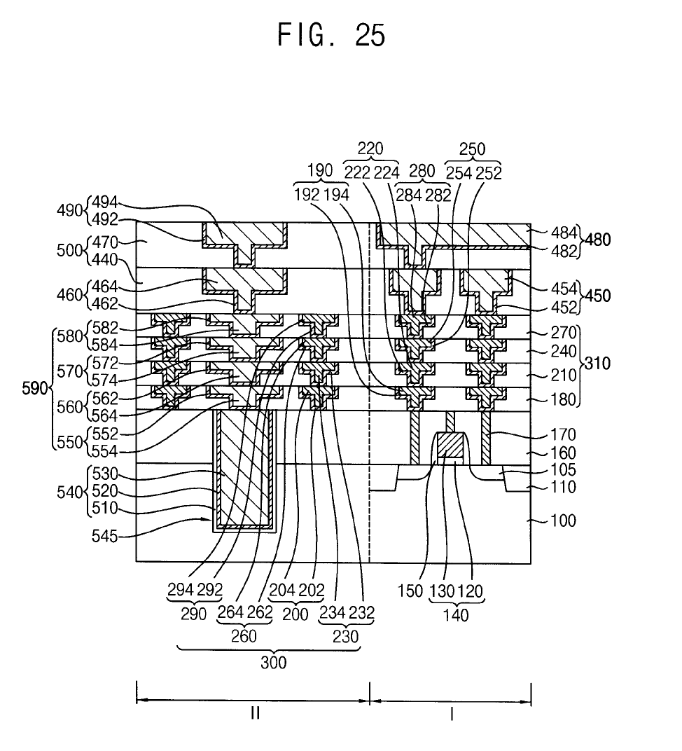

FIG. 25 is a vertical cross-sectional view illustrating a semiconductor device in accordance with some embodiments. The semiconductor device may be substantially the same as or similar to that of FIGS. 1 and 2, except that the semiconductor device may include a second via structure 540 and a contact structure 590 instead of the first via structure 430.

Thus, like reference numerals refer to like elements, and detailed descriptions thereon are omitted herein.

Referring to FIG. 25, the semiconductor device may include an insulating interlayer 160 and a first low-k dielectric layer structure 310 sequentially stacked on a first substrate 100, the second via structure 540 through at least a portion of the first substrate 100 and the insulating interlayer 160, the contact structure 590 in the first low-k dielectric layer structure 310 on a top surface of the second via structure 540, and a first blocking layer pattern structure 300 that may be spaced apart from the contact structure 590 in the first low-k dielectric layer structure 310 and surround a sidewall of the contact structure 590.

The semiconductor device may further include circuit elements (not shown), wirings 190, 220, 250, 280, 450, 460, 480 and 490, a second low-k dielectric layer structure 500, etc.

The second via structure 540 may include a first insulation layer pattern 510 and a first barrier layer pattern 520 sequentially stacked on an inner wall of a seventh trench 545 through at least a portion of the first substrate 100 and the insulating interlayer 160, and a via electrode 530 filling a remaining portion of the seventh trench 545 on the first barrier layer pattern 520.

The contact structure 590 may include first, second, third and fourth contacts 550, 560, 570 and 580 in the first, second, third and fourth low-k dielectric layers 180, 210, 240 and 270, respectively, included in the first low-k dielectric layer structure 310 in the second region II. The level of the contacts included in the contact structure 590 contained by the first low-k dielectric layer structure 310 may be at the levels of the low-k dielectric layers included in the first low-k dielectric layer structure 310. As the semiconductor device may include multiple second via structures 540, multiple contact structures 590 contacting top surfaces of the second via structures 540 may be formed.

In FIG. 25, the first low-k dielectric layer structure 310 may include the first to fourth low-k dielectric layers 180, 210, 240 and 270, and thus the first contact 550 may be formed through the first low-k dielectric layer 180, and may include an eighteenth metal pattern 554 and an eighteenth barrier pattern 552 surrounding a sidewall and a bottom of the eighteenth metal pattern 554. The second contact 560 may be formed through the second low-k dielectric layer 210, and may include a nineteenth metal pattern 564 and a nineteenth barrier pattern 562 surrounding a sidewall and a bottom of the nineteenth metal pattern 564. The third contact 570 may be formed through the third low-k dielectric layer 240, and may include a twentieth metal pattern 574 and a twentieth barrier pattern 572 surrounding a sidewall and a bottom of the twentieth metal pattern 574. The fourth contact 580 may be formed through the fourth low-k dielectric layer 270, and may include a twenty first metal pattern 584 and a twenty first barrier pattern 582 surrounding a sidewall and a bottom of the twenty first metal pattern 584.

In some embodiments, the first to fourth contacts 550, 560, 570 and 580 may directly contact each other. In FIG. 25, the first to fourth contacts 550, 560, 570 and 580 may completely overlap in a vertical direction so that the contact structure 590 may have a vertical sidewall as a whole, however, other embodiments may have different orientations. That is, as long as the first to fourth contacts 550, 560, 570 and 580 directly contact each other, in other embodiments, the vertical connection structure may have different structures.

The first to fourth contacts 550, 560, 570 and 580 may be formed in the processes for forming the first to fourth wirings 190, 220, 250 and 280 and the first to fourth blocking layer patterns 200, 230, 260 and 290. Thus, the first to fourth contacts 550, 560, 570 and 580 may be formed by a double damascene process, and some of them may be formed by a single damascene process. In FIG. 25, the first to fourth contacts 550, 560, 570 and 580 formed by a double damascene process are shown.

The eighteenth to twenty first barrier patterns 552, 562, 572 and 582 included in the first to fourth contacts 550, 560, 570 and 580, respectively, may include a metal nitride, e.g., titanium nitride, tantalum nitride, tungsten nitride, copper nitride, aluminum nitride, or the like, and the eighteenth to twenty first metal patterns 554, 564, 574 and 584 may include a metal, e.g., copper, aluminum, tungsten, titanium, tantalum, or the like.

The first blocking layer pattern structure 300 may surround a sidewall of the contact structure 590 in the first low-k dielectric layer structure 310 on a top surface of the second via structure 540. Thus, the first blocking layer pattern structure 300 may prevent or reduce the cross-talk or noise due to the coupling of the multiple second via structures 540 as well as the coupling of the contact structures 590 on the second via structures 540.

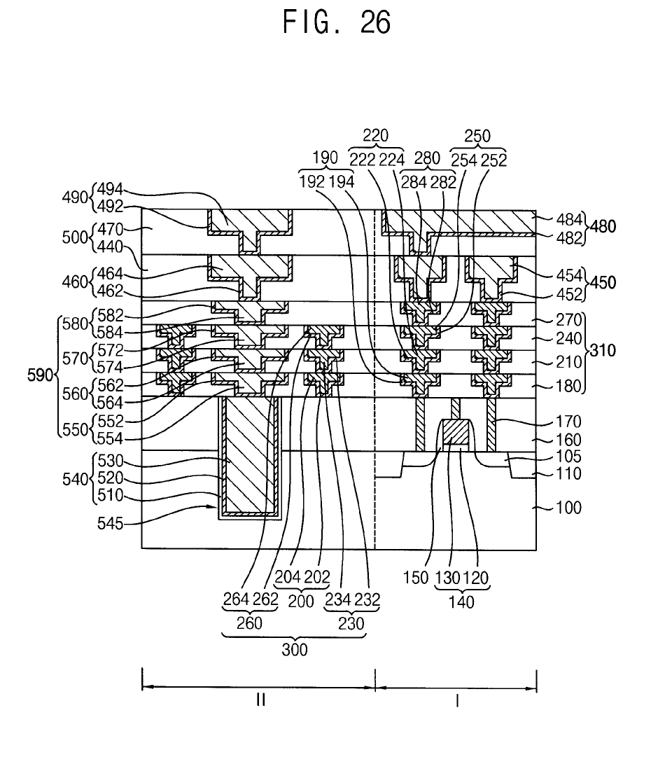

Unlike that of FIG. 25, the first blocking layer pattern structure 300 may not be formed in all of the first to fourth low-k dielectric layers 180, 210, 240 and 270 included in the first low-k dielectric layer structure 310, which may be shown in FIG. 26.

That is, the first blocking layer pattern structure 300 may include some of the first to fourth blocking layer patterns 200, 230, 260 and 290, and for example, may include the first to third blocking layer patterns 200, 230 and 260 as shown in FIG. 26. Moreover, although the first to third blocking layer patterns 200, 230 and 260 contact each other in FIG. 26, in other embodiments, one or more of the blocking layer patterns may be separated by a low-k dielectric layer such as one or more of the first to fourth low-k dielectric layers 180, 210, 240 and 270.

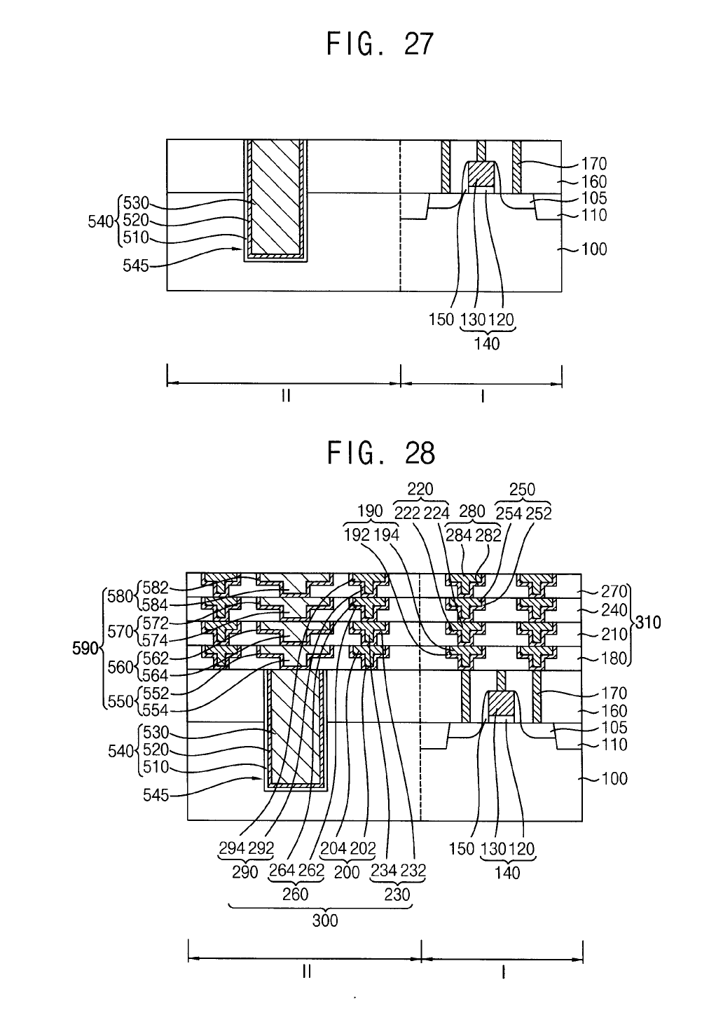

FIGS. 27 and 28 are cross-sectional views illustrating stages of a method of manufacturing a semiconductor device in accordance with some embodiments. This method may include processes substantially the same as or similar to those illustrated with reference to FIGS. 5 to 19, and thus like reference numerals refer to like elements, and detailed descriptions thereon are omitted herein.

Referring to FIG. 27, a process substantially the same as or similar to that illustrated with reference to FIG. 5 may be performed.

That is, a gate structure 140 and a gate spacer 150 may be formed on a first substrate 100 having an isolation layer 110 thereon, a first impurity region 105 may be formed, and an insulating interlayer 160 and a contact plug 170 may be formed.

Processes substantially the same as or similar to those illustrated with reference to FIGS. 10 to 18 may be performed.

That is, after forming a seventh trench 545 through a portion of the first substrate 100 and the insulating interlayer 160, an insulation layer and a barrier layer may be sequentially formed on an inner wall of the seventh trench 545, and an electrode layer may be formed to sufficiently fill the seventh trench 545. Upper portions of the electrode layer, the barrier layer and the insulation layer may be planarized until a top surface of the insulating interlayer 160 may be exposed to form a second via structure 540 in the seventh trench 545. The second via structure 540 may include a first insulation layer pattern 510, a first barrier layer pattern 520 and a via electrode 530.

Referring to FIG. 28, processes substantially the same as or similar to those illustrated with reference to FIGS. 6 to 9 may be performed.

That is, a first low-k dielectric layer structure 310 may be formed on the insulating interlayer 160, and first to fourth wirings 190, 220, 250 and 280 and first to fourth blocking layer patterns 200, 230, 260 and 290 may be formed in the first low-k dielectric layer structure 310. First to fourth contacts 550, 560, 570 and 580 may be sequentially formed on the second via structure 540 in the second region II together with the first to fourth wirings 190, 220, 250 and 280 and the first to fourth blocking layer patterns 200, 230, 260 and 290, respectively.

In some embodiments, the first to fourth contacts 550, 560, 570 and 580 may be formed by damascene processes when the first to fourth wirings 190, 220, 250 and 280 and the first to fourth blocking layer patterns 200, 230, 260 and 290 are formed in the first to fourth low-k dielectric layers 180, 210, 240 and 270, respectively, and thus may have shapes similar thereto.

Alternatively, the contact structure 590 may be formed by additional etching and electroplating processes to have a single pattern, after forming the first low-k dielectric layer structure 310, the first to fourth wirings 190, 220, 250 and 280, and the first to fourth blocking layer patterns 200, 230, 260 and 290.

Referring to FIG. 25 again, a process substantially the same as or similar to that illustrated with reference to FIGS. 1 to 2 may be performed to manufacture the semiconductor device. In this case, a seventh wiring 460 may be formed to contact a top surface of the contact structure 590.

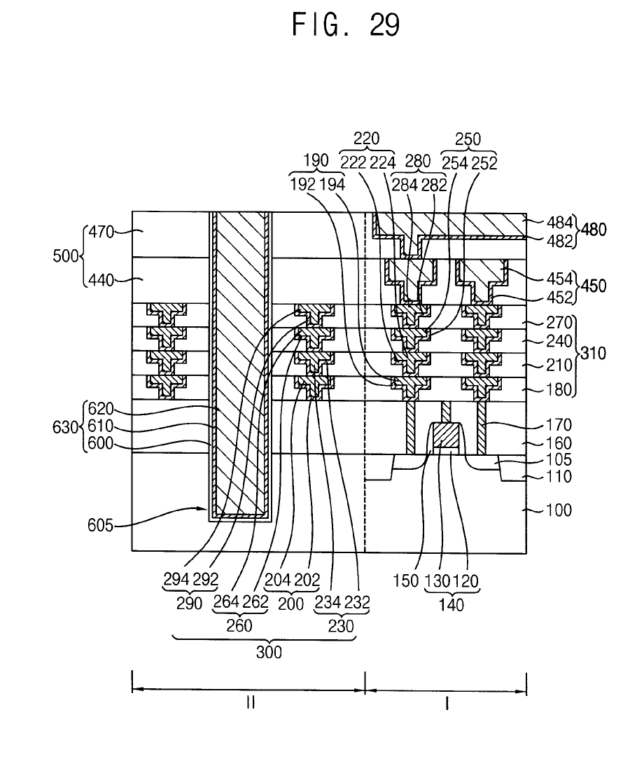

FIG. 29 is a vertical cross-sectional view illustrating a semiconductor device in accordance with some embodiments. The semiconductor device may be substantially the same as or similar to that of FIGS. 1 and 2, except that the semiconductor device may include a third via structure 630 instead of the first via structure 430 and the seventh and eighth wirings 460 and 490. Thus, like reference numerals refer to like elements, and detailed descriptions thereon are omitted herein.

Referring to FIG. 29, the semiconductor device may include an insulating interlayer 160 and first and second low-k dielectric layer structures 310 and 500 sequentially stacked on a first substrate 100, the third via structure 630 through at least a portion of the first substrate 100, the insulating interlayer 160 and the first and second low-k dielectric layer structures 310 and 500, and a first blocking layer pattern structure 300 that may be spaced apart from third via structure 630 in the first low-k dielectric layer structure 310 and surround a sidewall of the third via structure 630.

The semiconductor device may further include circuit elements (not shown), first to sixth wirings 190, 220, 250, 280, 450 and 480, and other structures as described above.

The third via structure 630 may be formed in an eighth trench 605 through the first and second low-k dielectric layer structures 310 and 500, the insulating interlayer 160 and at least a portion of the first substrate 100. That is, the third via structure 630 may include a first insulation layer pattern 600 and a first barrier layer pattern 610 sequentially stacked on an inner wall of the eighth trench 605, and a via electrode 620 filling a remaining portion of the eighth trench 605 on the first barrier layer pattern 610.

The first blocking layer pattern structure 300 may surround a portion of a sidewall of the third via structure 630 in the first low-k dielectric layer structure 310 that may be easily damaged when compared to the second low-k dielectric layer structure 500, so that the damage or shock to the first low-k dielectric layer structure 310 when the third via structure 630 is formed may be efficiently reduced or blocked.

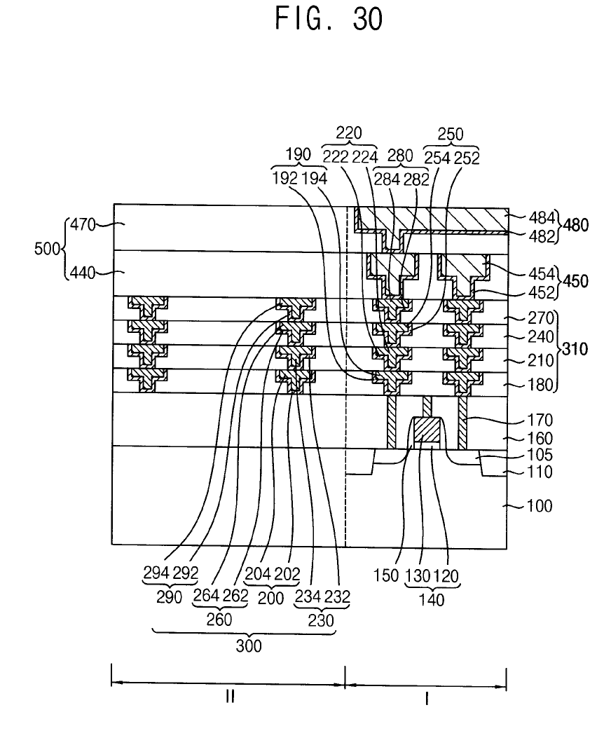

FIG. 30 is a cross-sectional view illustrating a stage of a method of manufacturing a semiconductor device in accordance with some embodiments. This method may include processes substantially the same as or similar to those illustrated with reference to FIGS. 5 to 19, and thus like reference numerals refer to like elements, and detailed descriptions thereon are omitted herein.

Referring to FIG. 30, processes substantially the same as or similar to those illustrated with reference to FIGS. 5 to 9 and 1 and 2 may be performed.

That is, circuit elements may be formed on a first substrate 100, and an insulating interlayer 160 and first and second low-k dielectric layer structures 310 and 500 may be sequentially stacked. In this case, the first blocking layer pattern structure 300 and the first to sixth wirings 190, 220, 250, 280, 450 and 480 may be formed, however, the processes for forming the first via structure 430 illustrated with reference to FIGS. 10 to 19 may not be performed.

Referring to FIG. 29 again, processes substantially the same as or similar to those illustrated with reference to FIGS. 10 to 19 may be performed to manufacture the semiconductor device.

That is, an eighth trench 605 may be formed through the first and second low-k dielectric layer structures 310 and 500, the insulating interlayer 160 and at least a portion of the first substrate 100, and a third via structure 630 may be formed to fill the eighth trench 605. The third via structure 630 may include a first insulation layer pattern 600 and a first barrier layer pattern 610 sequentially stacked on an inner wall of the eighth trench 605, and a via electrode 620 filling a remaining portion of the eighth trench 605 on the first barrier layer pattern 610.

When the eighth trench 605 is formed, a portion of the first low-k dielectric layer structure 310 adjacent to the eighth trench 605 may be damaged or shocked by a chemical, however, other portions of the first low-k dielectric layer structure 310 may not be damaged or shocked or such effects may be reduced due to the first blocking layer pattern structure 300.

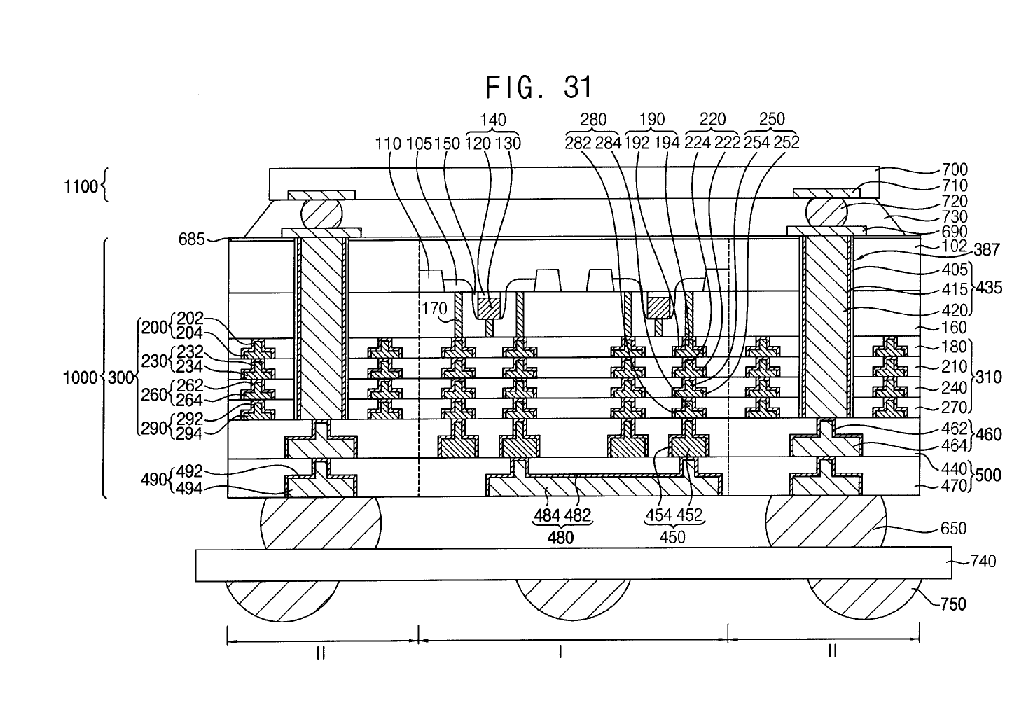

FIG. 31 is a vertical cross-sectional view illustrating a semiconductor package in accordance with some embodiments. The semiconductor package may include the semiconductor device illustrated with reference to FIGS. 1 and 2, and thus like reference numerals refer to like elements, and detailed descriptions thereon are omitted herein.

Referring to FIG. 31, the semiconductor package may include a first semiconductor chip 1000 and a second semiconductor chip 1100 sequentially stacked on a package substrate 740. The semiconductor package may further include first and second conductive bumps 650 and 720, a molding member 730 and an external connection terminal 750.

The package substrate 740 may be an insulation substrate in which circuit patterns (not shown) are printed, e.g., a printed circuit board (PCB) or other similar substrate. The external connection terminal 750 may be formed on a lower surface of the package substrate 740, so that the semiconductor package may be mounted on a module substrate (not shown) through the external connection terminal 750.

The first semiconductor chip 1000 may be mounted on the package substrate 740 via the first conductive bump 650, and may have a structure substantially the same as or similar to that of the semiconductor device of FIG. 1, except that the first semiconductor chip 1000 may include a second substrate 102 and a fourth via structure 435 instead of the first substrate 100 and the first via structure 430. The first conductive bump 650 may include a metal, e.g., silver, copper, etc., or an alloy, e.g., solder, or other similar materials.

The fourth via structure 435 may be formed in a first opening 387 through the second substrate 102 and the first and second low-k dielectric layer structures 310 and 500, and may include a via electrode 420, a second barrier layer pattern 415 and a second insulation layer pattern 405. The second insulation layer pattern 405 and the second barrier layer pattern 415 may be sequentially stacked on a sidewall of the first opening 387, and the via electrode 420 may be formed on the second barrier layer pattern 415 to fill a remaining portion of the first opening 387. Thus, the second bather layer pattern 415 may surround a sidewall of the via electrode 420, the second insulation layer pattern 405 may be formed on a sidewall of the second barrier layer pattern 415, and a top surface of the via electrode 420 may not be covered by the second barrier layer pattern 415 or the second insulation layer pattern 405 but may be exposed.

The fourth via structure 435 may be electrically connected to the package substrate 740 through seventh and eighth wirings 460 and 490 and the first conductive bump 650.

In an example embodiment, the first semiconductor chip 1000 may be a chip equipped with logic devices, e.g., a central processing unit (CPU), an application processor (AP), or other types of circuits.

A fourth protection layer pattern 685 may be formed on a surface of the second substrate 102 adjacent to the exposed top surface of the via electrode 420, and a first pad 690 may be formed on the exposed top surface of the via electrode 420.

The second semiconductor chip 1100 may include a third substrate 700 having a second pad 710 at a lower portion thereof, and circuit elements (not shown) may be formed on the third substrate 700. In an example embodiment, the semiconductor chip 1100 may be a chip equipped with a dynamic random access memory (DRAM) device, a static random access memory (SRAM) device, a flash memory device, or other types of circuits.

The first and second semiconductor chips 1000 and 1100 may be electrically connected to each other via the first and second pads 690 and 710 and the second conductive bump 720, and the molding member 730 may be formed therebetween. The molding member 730 may include, e.g., epoxy molding compound (EMC) or other similar materials.

As mentioned above, the first low-k dielectric layer structure 310 may not be damaged or have reduced damages and may have increased stability due to the first blocking layer pattern structure 300 in the first semiconductor chip 1000, so that the semiconductor package may have enhanced reliability.

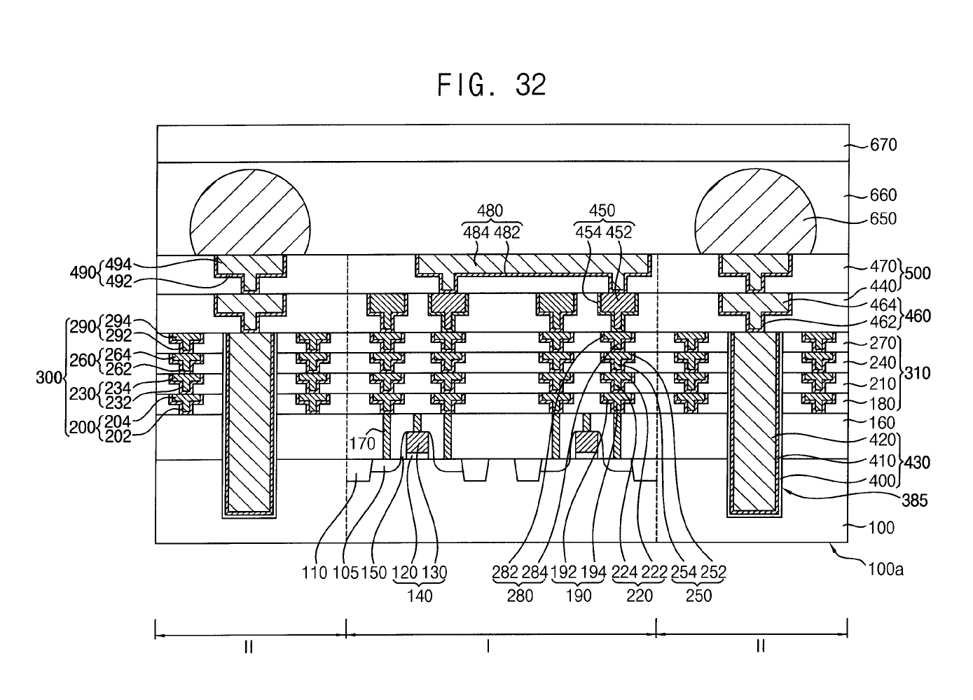

FIGS. 32 to 37 are cross-sectional views illustrating stages of a method of manufacturing a semiconductor package in accordance with some embodiments. This method may include processes substantially the same as or similar to those illustrated with reference to FIGS. 1 to 19, and thus like reference numerals refer to like elements, and detailed descriptions thereon are omitted herein.

Referring to FIG. 32, in the semiconductor device of FIGS. 1 and 2, a first conductive bump 650 may be formed on the second low-k dielectric layer structure 500 to contact a top surface of the eighth wiring 490, which may be formed at a surface of the first substrate 100 opposed to a first surface 100a thereof, an adhesion layer 660 may be formed on the second low-k dielectric layer structure 500 and the sixth wiring 480 to cover the first conductive bump 650, and a handling substrate 670 may be attached to the adhesion layer 660.

The first conductive bump 650 may be formed to include a metal, e.g., silver, copper, etc., or an alloy, e.g., solder, or other similar materials, and the handling substrate 670 may be, e.g., a glass substrate, or other similar substrate.

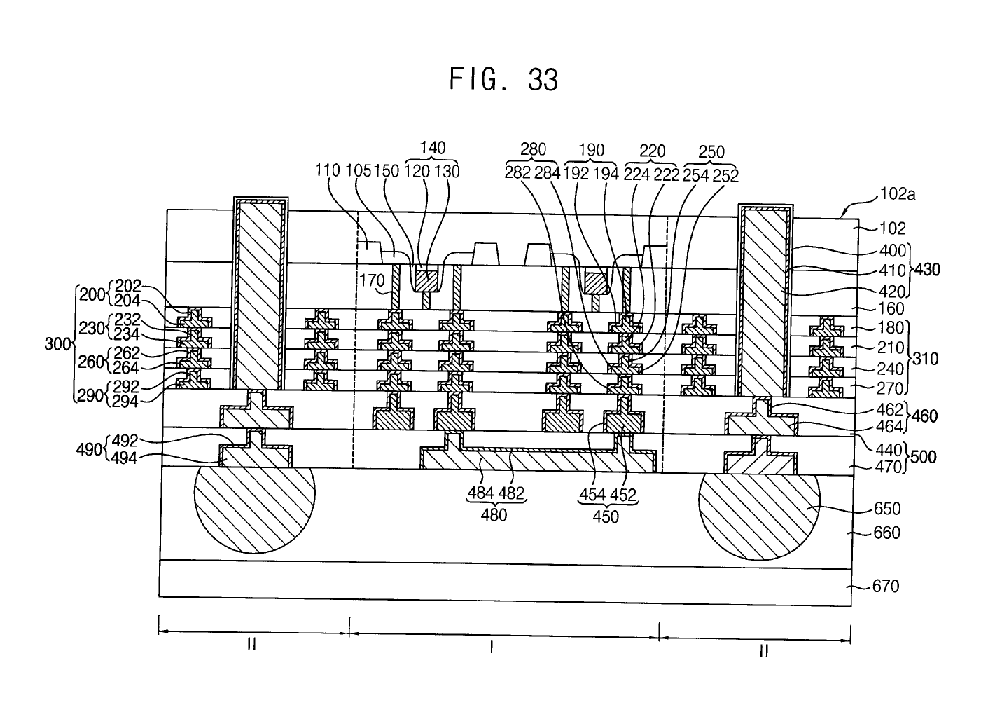

Referring to FIG. 33, the first substrate 100 may be overturned using the handling substrate 670 so that a first surface 100a of the first substrate 100 may face upward. A portion of the first substrate 100 adjacent to the first surface 100a may be removed to expose a portion of the first via structure 430. Thus, the first substrate 100 may be transformed into a second substrate 102 having a thickness smaller than that of the first substrate 100, and an upper surface of the second substrate 102 may be referred to as a second surface 102a.

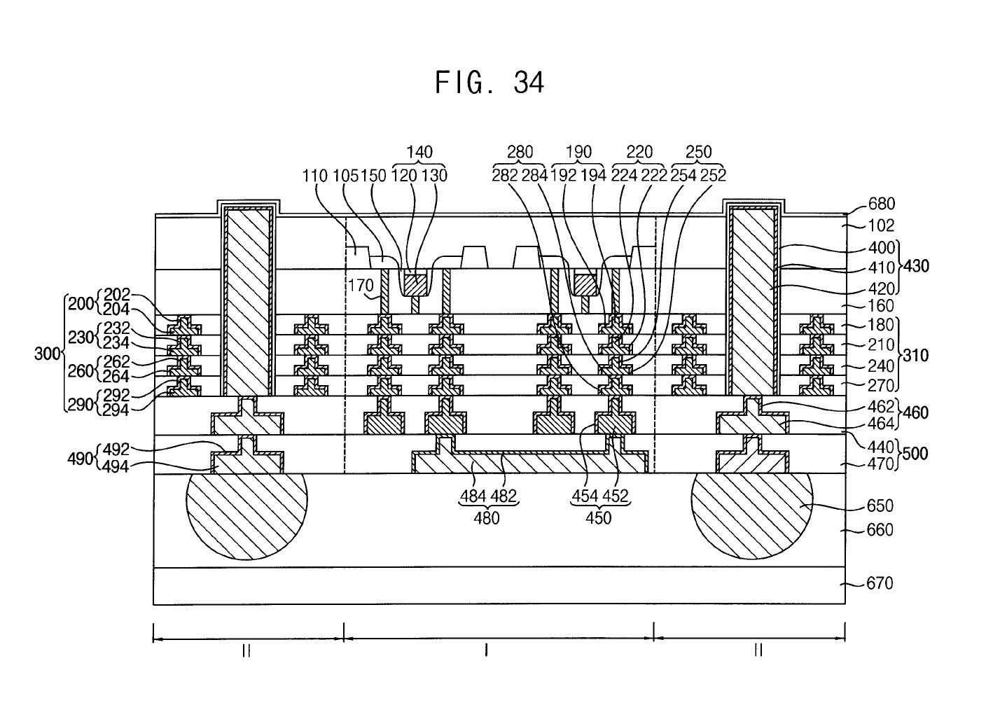

Referring to FIG. 34, a fourth protection layer 680 may be formed on the second surface 102a of the second substrate 102 and the exposed portion of the first via structure 430.

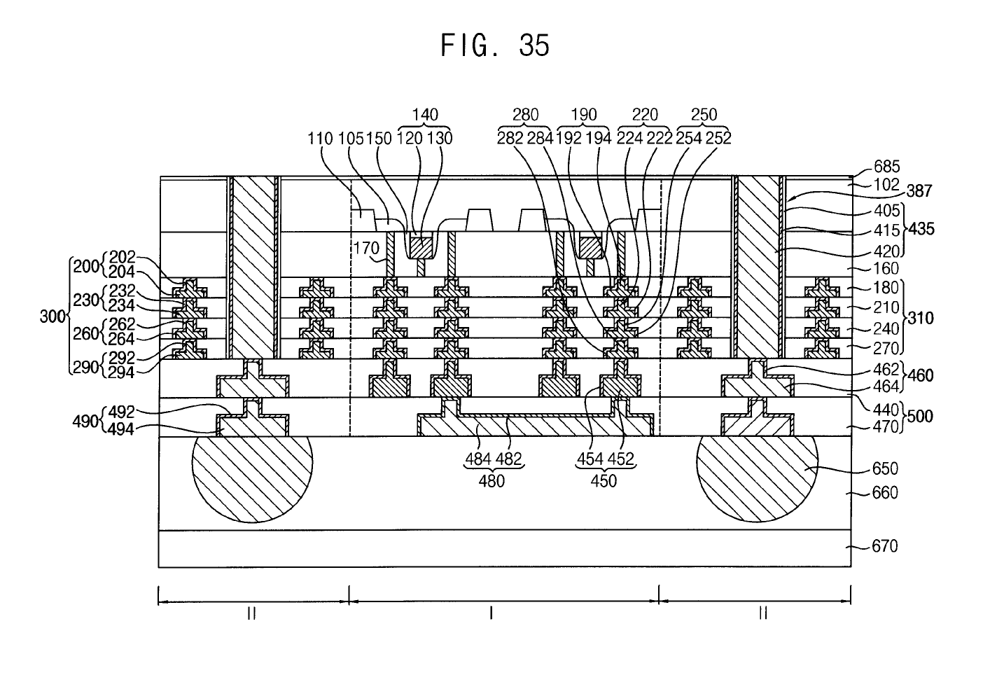

Referring to FIG. 35, the exposed portion of the first via structure 430 and a portion of the protection layer 680 thereon may be removed by a polishing process.

By the polishing process, the first insulation layer pattern 400 and the first barrier layer pattern 410 of the first via structure 430 may be transformed into a second insulation layer pattern 405 and a second barrier layer pattern 415, respectively. The second barrier layer pattern 415 may surround a sidewall of the via electrode 420, and the second insulation layer pattern 405 may be formed on a sidewall of the second barrier layer pattern 415. Thus, the first via structure 430 may be transformed into a fourth via structure 435. The fifth trench 385 in which the first via structure 430 may be formed may be transformed into a first opening 387, and the fourth protection layer 680 may be transformed into a fourth protection layer pattern 685.

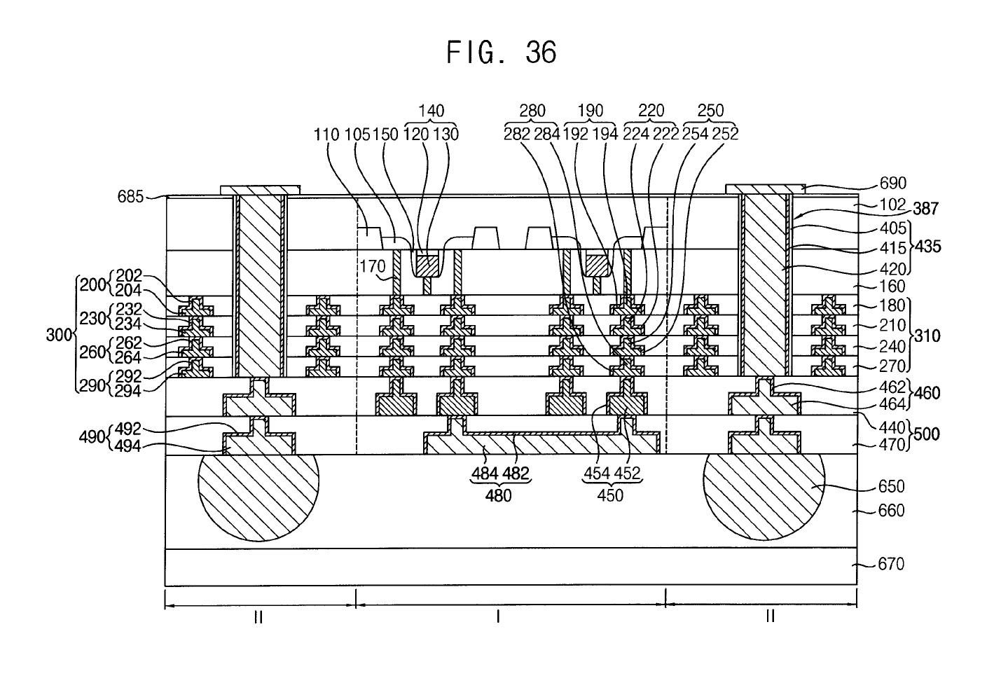

Referring to FIG. 36, a first pad 690 may be formed on the exposed via electrode 420. The first pad 690 may be formed to include a conductive material.

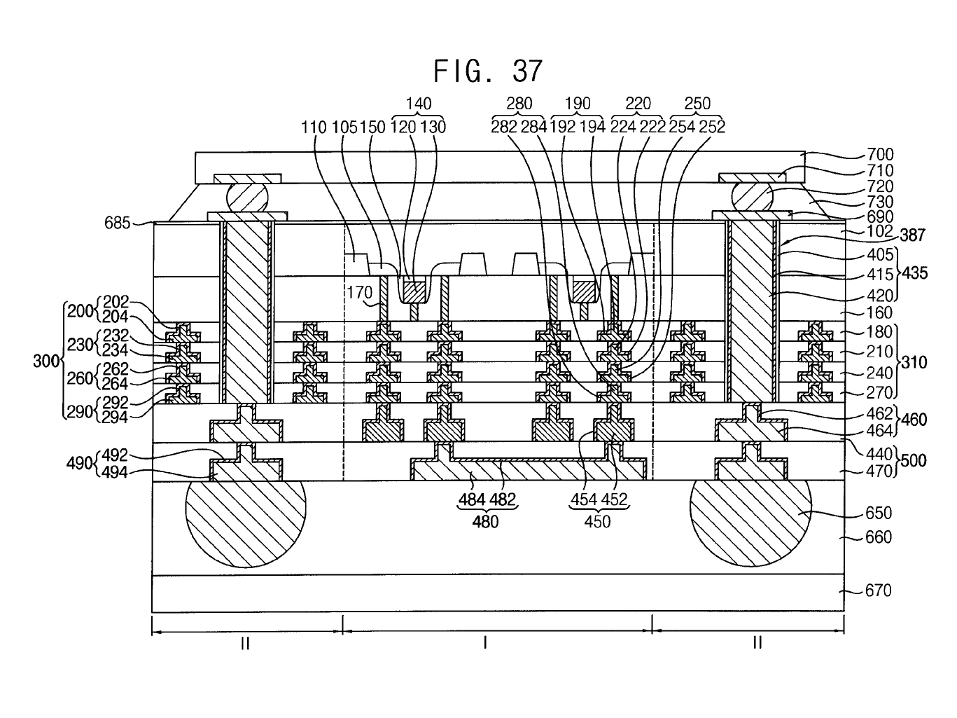

Referring to FIG. 37, after forming a second conductive bump 720 on the first pad 690, a third substrate 700 having a second pad 710 at a lower portion thereof may be pressed onto the second conductive bump 720 to be attached thereto. The second pad 710 may include a conductive material, and may be electrically connected to the first pad 690 by the second conductive bump 720.

A molding member 730 covering the first and second pads 690 and 710 and the second conductive bump 720 may be formed between the fourth protection layer pattern 685 and the third substrate 700. The molding member 730 may include, e.g., EMC or other similar materials.

Referring to FIG. 31 again, after removing the adhesion layer 660, the first conductive bump 650 may be pressed onto the package substrate 740 to be attached thereto, so that the semiconductor package may be manufactured. An external connection terminal 750 may be formed on a lower surface of the package substrate 740, and thus the semiconductor package may be mounted on a module substrate (not shown) through the external connection terminal 750.

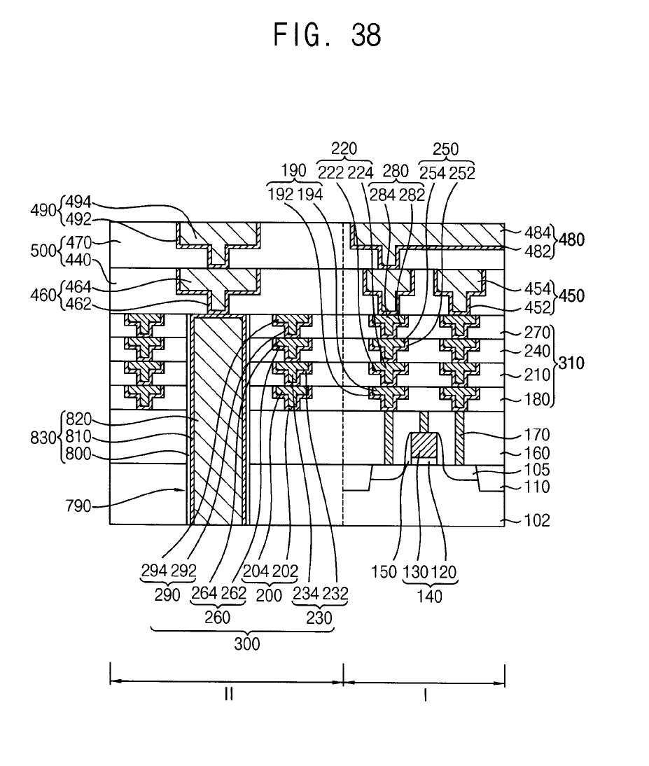

FIG. 38 is a vertical cross-sectional view illustrating a semiconductor device in accordance with some embodiments. The semiconductor device may be substantially the same as the semiconductor device illustrated with reference to FIGS. 1 and 2, except that the semiconductor device may include a second substrate 102 and a fifth via structure 830 instead of the first substrate 100 and the first via structure 430. Thus, like reference numerals refer to like elements, and detailed descriptions thereon are omitted herein.

Referring to FIG. 38, the semiconductor device may include an insulating interlayer 160 and first and second low-k dielectric layer structures 310 and 500 sequentially stacked on the second substrate 102, the fifth via structure 830 through at least a portion of the second substrate 102 and the insulating interlayer 160, and a first blocking layer pattern structure 300 that may be spaced apart from fifth via structure 830 in the first low-k dielectric layer structure 310 and surround a sidewall of the fifth via structure 830.

The semiconductor device may further include circuit elements (not shown), wirings 190, 220, 250, 280, 450, 480, 460, 490, etc.

The fifth via structure 830 may be formed in a second opening 790 through the second substrate 102, the insulating interlayer 160 and the first low-k dielectric layer structure 310. The fifth via structure 830 may include a third insulation layer pattern 800 on a sidewall of the second opening 790, a third barrier layer pattern 810 that may be formed on a sidewall of the third insulation layer pattern 800 and at an upper portion of the second opening 790 and contact the seventh wiring 460, and a via electrode 820 filling a remaining portion of the second opening 790 on the third bather layer pattern 810. Thus, a top surface and a sidewall of the via electrode 820 may be covered by the third barrier layer pattern 810, and a sidewall of the third barrier layer pattern 810 may be covered by the third insulation layer pattern 800.

The via electrode 820 of the fifth via structure 830 may be exposed at a lower surface of the second substrate 102.

The semiconductor device may have enhanced reliability due to the first blocking layer pattern structure 300 surrounding the sidewall of the fifth via structure 830.

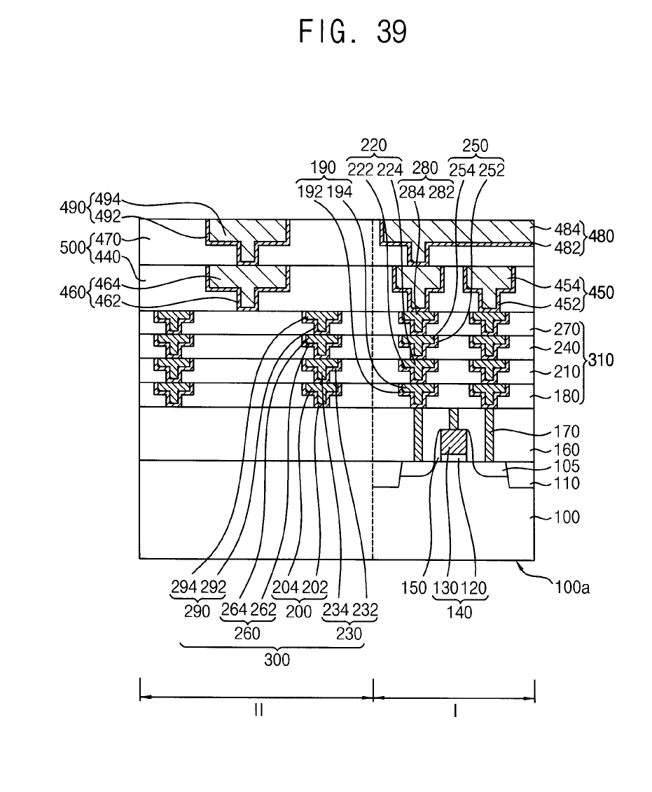

FIGS. 39 to 41 are cross-sectional views illustrating stages of a method of manufacturing a semiconductor package in accordance with some embodiments. This method may include processes substantially the same as or similar to those illustrated with reference to FIGS. 1 to 19, and thus like reference numerals refer to like elements, and detailed descriptions thereon are omitted herein.

Referring to FIG. 39, processes substantially the same as or similar to those illustrated with reference to FIGS. 5 to 9 may be performed to form circuit elements, an insulating interlayer 160, a first low-k dielectric layer structure 310, first to fourth wirings 190, 220, 250 and 280, and a first blocking layer pattern structure 300 may be formed on a surface of the first substrate 100 opposed to a first surface 100a thereof.

Processes substantially the same as or similar to those illustrated with reference to FIGS. 1 to 2 may be performed to form a second low-k dielectric layer structure 500 on the first low-k dielectric layer structure 310, and fifth to eighth wirings 450, 480, 460 and 490 may be formed.

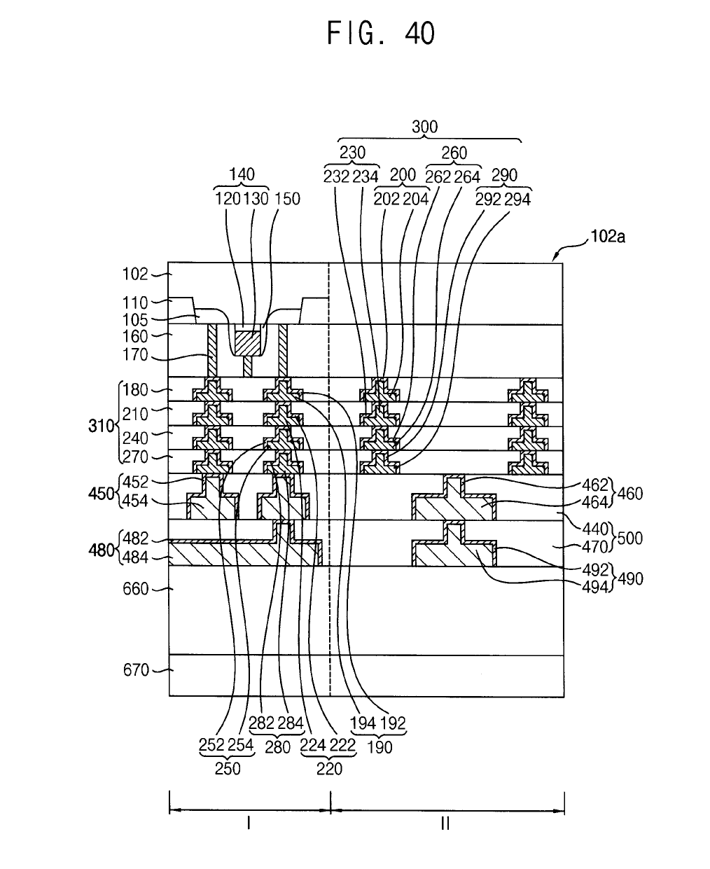

Referring to FIG. 40, an adhesion layer 660 may be formed on the second low-k dielectric layer structure 500 and the sixth and eighth wirings 480 and 490, and a handling substrate 670 may be attached to the adhesion layer 660. The first substrate 100 may be overturned using the handling substrate 670 so that the first surface 100a of the first substrate 100 may face upward.

A portion of the first substrate 100 adjacent to the first surface 100a may be removed so that the first substrate 100 may be transformed into a second substrate 102 having a thickness smaller than that of the first substrate 100, and an upper surface of the second substrate 102 may be referred to as a second surface 102a.

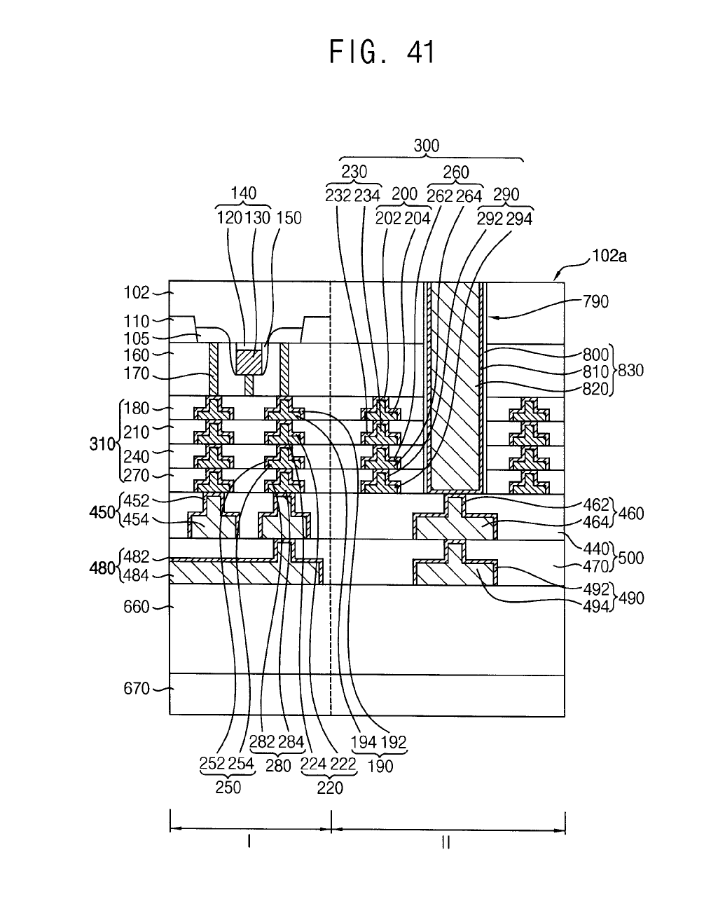

Referring to FIG. 41, processes substantially the same as or similar to those illustrated with reference to FIGS. 10 to 19 may be performed to form a second opening 790 through the second substrate 102, the insulating interlayer 160 and the first low-k dielectric layer 310, and a fifth via structure 830 may be formed to fill the second opening 790.

The fifth via structure 830 may include a third insulation layer pattern 800 on a sidewall of the second opening 790, a third barrier layer pattern 810 that may be formed on a sidewall of the third insulation layer pattern 800 and at a lower portion of the second opening 790 and contact the seventh wiring 460, and a via electrode 820 filling a remaining portion of the second opening 790 on the third barrier layer pattern 810. Thus, a sidewall and a bottom of the via electrode 820 may be covered by the third barrier layer pattern 810, and a sidewall of the third barrier layer pattern 810 may be covered by the third insulation layer pattern 800.

Referring to FIG. 39 again, after removing the adhesion layer 660 and the handling substrate 670, the second substrate 102 may be overturned so that the second surface 102a of the second substrate 102 may face downward to manufacture the semiconductor device.

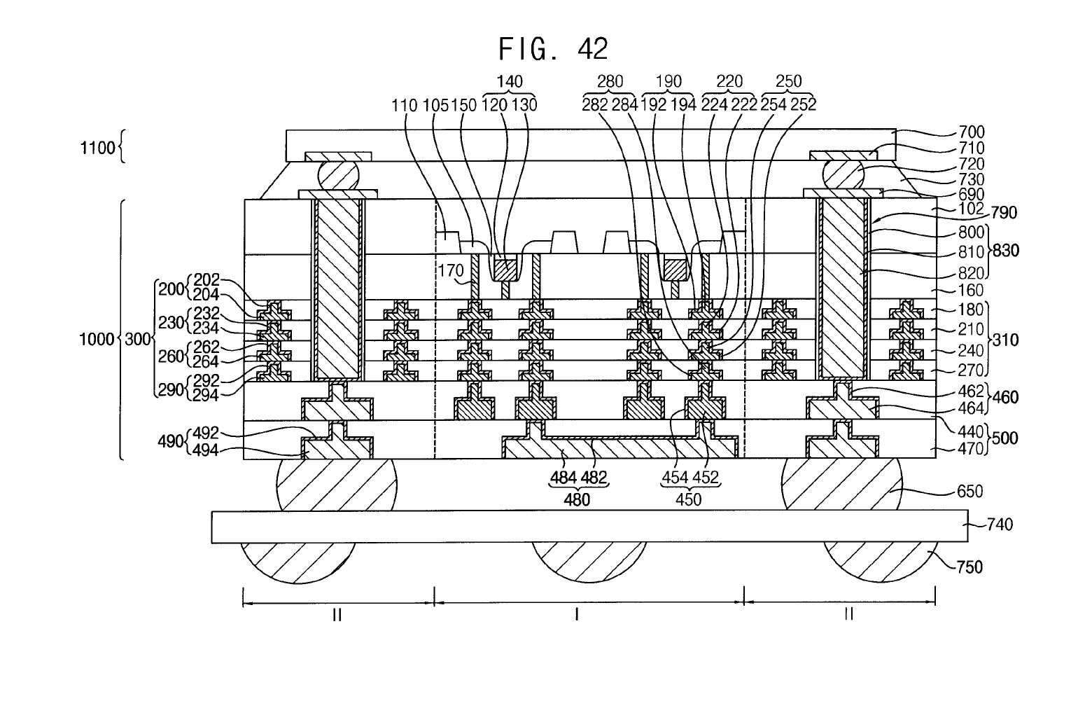

FIG. 42 is a vertical cross-sectional view illustrating a semiconductor package in accordance with some embodiments. The semiconductor package of FIG. 42 may be substantially the same as that of the semiconductor package of FIG. 31, except that the semiconductor package may include a fifth via structure 830 instead of the fourth via structure 435 and may not include the fourth protection layer pattern 685. Thus, like reference numerals refer to like elements, and detailed descriptions thereon are omitted herein.

Referring to FIG. 42, the semiconductor package may include a first semiconductor chip 1000 and a second semiconductor chip 1100 sequentially stacked on a package substrate 740. The semiconductor package may further include first and second conductive bumps 650 and 720, a molding member 730 and an external connection terminal 750.

The first semiconductor chip 1000 may include a second substrate 102 and the fifth via structure 830 in a second opening 790 through first and second low-k dielectric layer structures 310 and 500. The fifth via structure 830 may include a via electrode 820, a third barrier layer pattern 810 and a third insulation layer pattern 800, which have been previously explained with reference to FIG. 38.

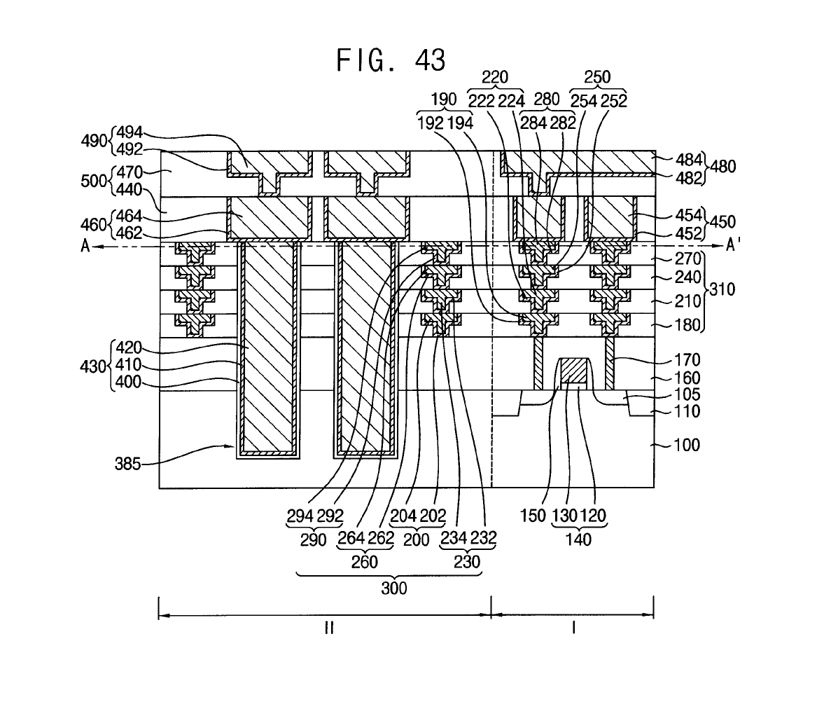

FIG. 43 is a vertical cross-sectional view illustrating a semiconductor device in accordance with some embodiments. The semiconductor device may be substantially the same as or similar to that of FIGS. 1 and 2. Thus, like reference numerals refer to like elements, and detailed descriptions thereon are omitted herein. However, the semiconductor device includes multiple via structures 430. Although two via structures 430 are illustrated, more than two via structures 430 may be included.

Sidewalls of the multiple via structures 430 are substantially surrounded by the first blocking layer pattern structure 300. Although only one is illustrated, in some embodiments, multiple sets of multiple via structures 430 and surrounding blocking layer pattern structure 300 may be present. Regardless, within one set, the multiple via structures 430 are surrounded by the corresponding blocking layer pattern structure 300. Accordingly, any physical damage or shock to a portion of a low-k dielectric layer structure due to forming a trench for a via structure may be prevented from propagating to other portions of the low-k dielectric layer structure.

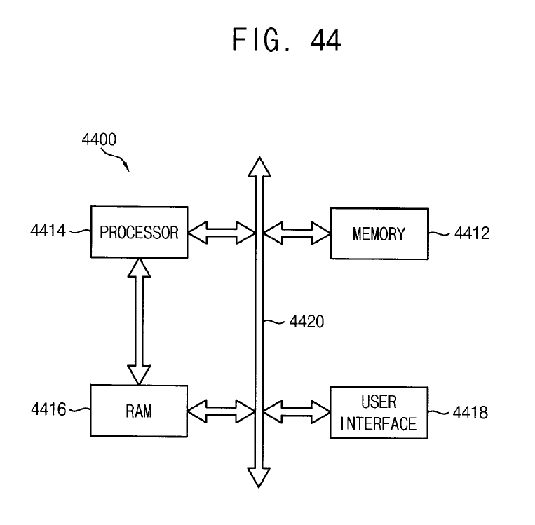

FIG. 44 is a schematic view of an electronic system which may include a semiconductor package in accordance with some embodiments. The electronic system 4400 may be part of a wide variety of electronic devices including, but not limited to portable notebook computers, Ultra-Mobile PCs (UMPC), Tablet PCs, servers, workstations, mobile telecommunication devices, and so on. For example, the electronic system 4400 may include a memory system 4412, a processor 4414, RAM 4416, and a user interface 4418, which may execute data communication using a bus 4420.

The processor 4414 may be a microprocessor or a mobile processor (AP). The processor 4414 may have a processor core (not illustrated) that can include a floating point unit (FPU), an arithmetic logic unit (ALU), a graphics processing unit (GPU), and a digital signal processing core (DSP Core), or any combinations thereof. The processor 4414 may execute the program and control the electronic system 4400.

The RAM 4416 may be used as an operation memory of the processor 4414. Alternatively, the processor 4414 and the RAM 4416 may be packaged in a single package body. The user interface 4418 may be used in inputting/outputting data to/from the electronic system 4400.

The memory system 4412 may store codes for operating the processor 4414, data processed by the processor 4414, or externally input data. The memory system 4412 may include a controller and a memory. The memory system may include an interface to computer readable media.

An embodiment includes a semiconductor device having a higher reliability.

An embodiment includes a method of manufacturing a semiconductor device having a higher reliability.

An embodiment includes a semiconductor package having a higher reliability.

An embodiment includes a method of manufacturing a semiconductor package having a higher reliability.

Some embodiments include a semiconductor device. The semiconductor device includes a first low-k dielectric layer structure including at least one first low-k dielectric layer sequentially stacked on a substrate, a via structure through at least a portion of the substrate and the first low-k dielectric layer structure, and a first blocking layer pattern structure spaced apart from the via structure in the first low-k dielectric layer structure. The first blocking layer pattern structure surrounds a sidewall of the first blocking layer structure.

In some embodiments, the first low-k dielectric layer structure may include multiple first low-k dielectric layers sequentially stacked, and the first blocking layer pattern structure may penetrate through at least one of the multiple first low-k dielectric layers and include multiple first blocking layer patterns connected to each other. Each of the first blocking layer patterns may penetrate through each of the at least one of the multiple first low-k dielectric layers.

In some embodiments, each of the first blocking layer patterns may have a rectangular annular shape, an octagonal annular shape or a circular annular shape when viewed from a top side.

In some embodiments, each of the first blocking layer patterns may include a lower portion and an upper portion connected to each other. A first inner diameter of each lower portion may be greater than a second inner diameter of each upper portion, and a first thickness of each lower portion may be smaller than a second thickness of each upper portion.

In some embodiments, each of the first blocking layer patterns may include a metal pattern and a barrier pattern surrounding a sidewall and a bottom of the metal pattern.

In some embodiments, the first blocking layer pattern structure may penetrate through the first low-k dielectric layer structure.

In some embodiments, the semiconductor device may further include a second blocking layer pattern structure spaced apart from the first blocking layer pattern structure in the first low-k dielectric layer structure. The second blocking layer pattern structure may surround a sidewall of the via structure.

In some embodiments, the semiconductor device may further include a second blocking layer pattern structure and a second wiring. The second blocking layer pattern structure may include at least one second blocking layer pattern sequentially stacked on the first low-k dielectric layer structure. The at least one second blocking layer pattern may have a dielectric constant higher than that of the at least one first low-k dielectric layer. The second wiring may be formed in the second low-k dielectric layer structure and contact a top surface of the via structure.

In some embodiments, the second low-k dielectric layer structure may include multiple second low-k dielectric layers sequentially stacked. The semiconductor device may further include a third blocking layer pattern structure through at least one of the multiple second low-k dielectric layers. The third blocking layer pattern structure may be connected to the first blocking layer pattern structure.

In some embodiments, the semiconductor device may further include an insulating interlayer between the substrate and the first low-k dielectric layer structure, and a ground wiring through the insulating interlayer. The ground wiring may be electrically connected to the first blocking layer pattern structure.

In some embodiments, the semiconductor device may further include an impurity region at an upper portion of the substrate. The impurity region may contact the ground wiring.

In some embodiments, the semiconductor device may further include an insulating interlayer between the substrate and the first low-k dielectric layer structure, at least one circuit element covered by the insulating interlayer on the substrate, at least one first wiring spaced apart from the first blocking layer pattern structure in the first low-k dielectric layer structure, and a contact plug electrically connecting the circuit element and the first wiring.

In some embodiments, the first blocking layer pattern structure may include a material substantially the same as that of the first wiring.

In some embodiments, the via structure may include a via electrode containing a metal, a barrier layer pattern surrounding a sidewall of the via electrode, and an insulation layer pattern surrounding at least a sidewall of the barrier layer pattern.

In some embodiments, the via structure may include a via electrode containing a metal, a barrier layer pattern surrounding a sidewall and a top surface of the via electrode, and an insulation layer pattern surrounding a sidewall of the barrier layer pattern.

Some embodiments include a semiconductor device. The semiconductor device includes an insulating interlayer on a substrate, a low-k dielectric layer structure including at least one low-k dielectric layer sequentially stacked on the insulating interlayer, a via structure through at least a portion of the substrate and the insulating interlayer, a contact structure on the via structure, and a blocking layer pattern structure spaced apart from the via structure in the low-k dielectric layer structure. The blocking layer pattern structure surrounds a sidewall of the contact structure.

Some embodiments include a method of manufacturing a semiconductor device. In the method, a first low-k dielectric layer structure is formed on a substrate. A first blocking layer pattern structure is formed in the first low-k dielectric layer structure. A via structure is formed through the first low-k dielectric layer structure and at least a portion of the substrate to be spaced apart from the first blocking layer pattern structure. A portion of a sidewall of the via structure is surrounded by the first blocking layer pattern structure.

In some embodiments, when the via structure is formed, the first low-k dielectric layer structure and at least a portion of the substrate may be etched to form a trench. An inner wall of the trench may be cleaned using a chemical. An insulation layer may be formed on the inner wall of the cleaned trench. A barrier layer may be formed on an inner wall of the insulation layer. A via electrode may be formed on the barrier layer using a metal to fill a remaining portion of the trench.

In some embodiments, when the first low-k dielectric layer structure is formed, multiple first low-k dielectric layers may be sequentially formed. When the first blocking layer pattern structure is formed in the first low-k dielectric layer structure, after forming the first low-k dielectric layers, multiple first blocking layer patterns may be formed to be connected to each other. The first blocking layer patterns may penetrate through the first low-k dielectric layers, respectively.

In some embodiments, when the first blocking layer patterns are formed to be connected to each other, first wirings may be formed. Each of the first wirings may penetrate through the first low-k dielectric layers, respectively. The first blocking layer patterns and the first wirings penetrating through the first low-k dielectric layers, respectively, may be formed by a damascene process using substantially the same material.

In some embodiments, after forming the via structure, a second low-k dielectric layer structure may be formed on the first low-k dielectric layer structure. The second low-k dielectric layer structure may have a dielectric constant higher than that of the first low-k dielectric layer structure. A second wiring and a second blocking layer pattern structure may be formed in the second low-k dielectric layer structure. The second wiring may be connected to the via structure, and be connected to the first blocking layer pattern structure and surround at least a portion of a sidewall of the second wiring.

In some embodiments, before forming the first low-k dielectric layer structure, an impurity region may be formed at an upper portion of the substrate. An insulating interlayer may be formed on the substrate. A ground wiring may be formed through the insulating interlayer to contact the impurity region. The first blocking layer pattern structure may be formed to be electrically connected to the ground wiring.

Some embodiments include a semiconductor package. The semiconductor package includes a first semiconductor chip and a second semiconductor chip. The first semiconductor chip includes a first low-k dielectric layer structure including at least one first low-k dielectric layer sequentially stacked on a substrate, a via structure through the substrate and the first low-k dielectric layer structure, and a blocking layer pattern structure spaced apart from the via structure in the first low-k dielectric layer structure. The blocking layer pattern structure surrounds a sidewall of the via structure. The second semiconductor chip is electrically connected to the first semiconductor chip through the via structure.

In some embodiments, the semiconductor package may further include an insulating interlayer between the substrate and the first low-k dielectric layer structure, at least one wiring in the first low-k dielectric layer structure, and a second low-k dielectric layer structure on the first low-k dielectric layer structure. The insulating interlayer may contain at least one circuit element therein. The at least one wiring may be electrically connected to the circuit element. The second low-k dielectric layer structure may contain a second wiring connected to the via structure.

Some embodiments include a method of manufacturing a semiconductor package. In the method, a first semiconductor chip is formed as follows. A first low-k dielectric layer structure is formed on a substrate. A first blocking layer pattern structure is formed in the first low-k dielectric layer structure. A via structure is formed through the first low-k dielectric layer structure and at least a portion of the substrate to be spaced apart from the first blocking layer pattern structure. A portion of a sidewall of the via structure is surrounded by the first blocking layer pattern structure. The substrate is partially removed to expose the via structure. A second semiconductor chip is formed. The first and second semiconductor chips electrically connected through the via structure.

In some embodiments, the semiconductor device may include a blocking layer pattern structure so that the physical damage or shock to a portion of a low-k dielectric layer structure due to the chemical used in forming a trench for a via structure may be prevented from propagating to other portions of the low-k dielectric layer structure. Additionally, the stress applied to the low-k dielectric layer structure by the via structure due to the difference of CTE between the via structure and the low-k dielectric layer structure may be blocked.

Furthermore, when multiple via structures is densely formed, the blocking layer pattern structure may reduce or prevent the cross-talk or noise due to the coupling of the via structures. Thus, when forming circuit elements are formed between the via structures, higher design freedom degree may be secured.

The foregoing is illustrative of some embodiments and is not to be construed as limiting thereof. Although some embodiments have been described, those skilled in the art will readily appreciate that many modifications are possible without materially departing from the novel teachings and advantages herein. Accordingly, all such modifications are intended to be included within the scope as defined in the claims. In the claims, means-plus-function clauses are intended to cover the structures described herein as performing the recited function and not only structural equivalents but also equivalent structures. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

1. A semiconductor device, comprising:
a first low-k dielectric layer structure including at least one first low-k dielectric layer sequentially stacked on a substrate;
a via structure extending through at least a portion of the substrate and the first low-k dielectric layer structure; and
a first blocking layer pattern structure spaced apart from the via structure in the first low-k dielectric layer structure, the first blocking layer pattern structure surrounding a sidewall of the first blocking layer structure.

2. The semiconductor device of claim 1, wherein:
the first low-k dielectric layer structure includes a plurality of first low-k dielectric layers sequentially stacked; and
the first blocking layer pattern structure penetrates through at least one of the plurality of first low-k dielectric layers and includes a plurality of first blocking layer patterns, each of the first blocking layer patterns penetrating through a corresponding one of the at least one of the plurality of first low-k dielectric layers.

3. The semiconductor device of claim 2, wherein the first blocking layer patterns are connected to each other.

4. The semiconductor device of claim 2, wherein:
each of the first blocking layer patterns includes a lower portion and an upper portion connected to each other; and
a first inner diameter of each lower portion is greater than a second inner diameter of each upper portion, and a first width of each lower portion is smaller than a second width of each upper portion.

5. The semiconductor device of claim 2, wherein each of the first blocking layer patterns includes:
a metal pattern; and
a barrier pattern surrounding a sidewall and a bottom of the metal pattern.

6. The semiconductor device of claim 2, wherein each of the first blocking layer patterns has an annular shape when viewed from a top side.

7. The semiconductor device of claim 1, further comprising a second blocking layer pattern structure spaced apart from the first blocking layer pattern structure in the first low-k dielectric layer structure, the second blocking layer pattern structure surrounding the sidewall of the via structure.

8. The semiconductor device of claim 1, further comprising:
a second low-k dielectric layer structure including at least one second low-k dielectric layer sequentially stacked on the first low-k dielectric layer structure, the at least one second low-k dielectric layer having a dielectric constant higher than that of the at least one first low-k dielectric layer; and
a second wiring in the second low-k dielectric layer structure, the second wiring contacting a top surface of the via structure.

9. The semiconductor device of claim 8, wherein:
the second low-k dielectric layer structure includes a plurality of second low-k dielectric layers sequentially stacked; and
further comprising a second blocking layer pattern structure through at least one of the plurality of second low-k dielectric layers, the second blocking layer pattern structure being connected to the first blocking layer pattern structure and spaced apart from the second wiring.

10. The semiconductor device of claim 1, further comprising:
an insulating interlayer between the substrate and the first low-k dielectric layer structure; and
a ground wiring through the insulating interlayer, the ground wiring being electrically connected to the first blocking layer pattern structure.

11. The semiconductor device of claim 10, further comprising an impurity region at an upper portion of the substrate, the impurity region contacting the ground wiring.

12. The semiconductor device of claim 1, further comprising:
an insulating interlayer between the substrate and the first low-k dielectric layer structure;
at least one circuit element covered by the insulating interlayer on the substrate;
at least one first wiring spaced apart from the first blocking layer pattern structure in the first low-k dielectric layer structure; and
a contact plug electrically connecting the circuit element and the at least one first wiring.

13. The semiconductor device of claim 12, wherein the first blocking layer pattern structure includes a material substantially the same as that of the first wiring.

14. The semiconductor device of claim 1, wherein the via structure includes:
a via electrode including a metal;
a barrier layer pattern surrounding a sidewall of the via electrode; and
an insulation layer pattern surrounding at least a sidewall of the barrier layer pattern.

15. The semiconductor device of claim 1, wherein the via structure includes:
a via electrode including a metal;
a barrier layer pattern surrounding a sidewall and a top surface of the via electrode; and
an insulation layer pattern surrounding a sidewall of the barrier layer pattern.

16. The semiconductor device of claim 1, wherein:
the via structure is referred to as a first via structure; and
further comprising a second via structure in the first low-k dielectric layer wherein the first blocking layer pattern structure is spaced apart from the second via structure in the first low-k dielectric layer structure and surrounds a sidewall of the first blocking layer structure.

17. A semiconductor device, comprising:
an insulating interlayer on a substrate;
a low-k dielectric layer structure including at least one low-k dielectric layer sequentially stacked on the insulating interlayer;
a via structure through at least a portion of the substrate and the insulating interlayer;
a contact structure on the via structure, the contact structure disposed in the low-k dielectric layer structure; and
a blocking layer pattern structure spaced apart from the contact structure in the low-k dielectric layer structure, the blocking layer pattern structure surrounding a sidewall of the contact structure.

18. The semiconductor device of claim 17, wherein:
the at least one low-k dielectric layer comprises a plurality of low-k dielectric layers; and
the contact structure is disposed in less than all of the low-k dielectric layers.

19-27. (canceled)

28. A semiconductor device, comprising:
a circuit formed on a substrate
a low-k dielectric layer formed on the substrate;
wirings electrically connected to the circuit and formed in the low-k dielectric layer;
a conductive structure including a via structure, the conductive structure extending through the low-k dielectric layer and at least part of the substrate; and
a blocking layer pattern structure disposed in the low-k dielectric layer and surrounding a sidewall of the conductive structure.

29. The semiconductor device of claim 28, wherein:
the blocking layer pattern structure includes a first blocking layer pattern and a second blocking layer pattern; and
the first blocking layer pattern and the second blocking layer pattern are concentric and spaced apart.

30. (canceled)
